(19) United States
(12) Patent Application Publication
(10) Pub. No.: US 2025/0251439 A1
(43) Pub. Date: Aug. 7, 2025

(54) DISPLAY PANEL, TEST METHOD THEREOF, AND DISPLAY DEVICE

(71) Applicant: Hefei Visionox Technology Co., Ltd., Hefei (CN)

(72) Inventors: Mengqing YOU, Hefei (CN); Xi ZHU, Hefei (CN); Dawei SUN, Hefei (CN)

(73) Assignee: Hefei Visionox Technology Co., Ltd., Hefei (CN)

(21) Appl. No.: 19/185,135

(22) Filed: Apr. 21, 2025

Related U.S. Application Data
(63) Continuation of application No. PCT/CN2023/135352, filed on Nov. 30, 2023.

(30) Foreign Application Priority Data
Jun. 13, 2023 (CN) 202310706955.8

(51) Int. Cl. G01R 31/28; H10D 86/40

(52) U.S. Cl. CPC G01R 31/2832; H10D 86/441

(57) ABSTRACT

A display panel includes pixel units, data lines, first fan-out lines located in an active area, second fan-out lines, test circuit units, and test signal lines located in a non-active area. A first fan-out line is electrically connected to a corresponding first data line. Each test circuit unit includes switches including first switches and second switches. First ends of the first switches are electrically connected to the first fan-out lines through corresponding second fan-out lines. First ends of second switches are electrically connected to corresponding second data lines through corresponding second fan-out lines. Second ends of switches electrically connected to corresponding pixel units in the same column are electrically connected to the same test signal line. Second ends of switches electrically connected to corresponding pixel units in two adjacent columns are electrically connected to different test signal lines.

### CROSS-REFERENCE TO RELATED APPLICATIONS

This application is a continuation of International Patent Application No. PCT/CN2023/135352, filed on Nov. 30, 2023, which claims priority to Chinese Patent Application No. 202310706955.8, filed on Jun. 13, 2023, disclosures of both of which are incorporated herein by reference in their entireties.

### FIELD

Embodiments of the present application relate to the field of display technology, for example, a display panel, a test method thereof, and a display device.

### BACKGROUND

After the fabrication of all layers of a display panel is completed, detection signals may be provided to the display panel via a test terminal in order to perform the inspection of the display panel, which is used to screen out defective display panels and prevent subsequent process waste caused by the defective display panels.

### SUMMARY

The present application provides a display panel, a test method thereof, and a display device.

One or more embodiments of the present applications provide a display panel. The display panel includes an active area and a non-active area. The display panel further includes a plurality of pixel units, a plurality of data lines, a plurality of first fan-out lines, a plurality of second fan-out lines, a plurality of test circuit units, and at least two test signal lines.

The plurality of pixel units are arranged in an array and located in the active area.

The plurality of data lines are located in the active area, where the plurality of data lines are electrically connected to pixel units in corresponding columns, the plurality of data lines extend in a column direction and are arranged in a row direction, and the plurality of data lines include at least two first data lines and at least two second data lines.

The plurality of first fan-out lines are located in the active area, where the plurality of first fan-out lines are electrically connected to corresponding first data lines.

The plurality of second fan-out lines, the plurality of test circuit units and the at least two test signal lines are located in the non-active area, where each test circuit unit among the plurality of test circuit units includes switches, and the switches includes a plurality of first switches and a plurality of second switches, first ends of the plurality of first switches are electrically connected through corresponding second fan-out lines to corresponding one first fan-out lines, first ends of the plurality of second switches are electrically connected through corresponding second fan-out lines to corresponding second data lines; second ends of switches electrically connected to corresponding pixel units in a same column are electrically connected to a same test signal line; and second ends of switches electrically connected to corresponding pixel units in two adjacent columns are electrically connected to different test signal lines.

One or more embodiments of the present applications also provide a display device. The display device includes a driver chip and the display panel in the embodiments, where the driver chip is electrically connected to second fan-out lines.

Embodiments of the present applications also provide a test method applied to the display panel in the embodiments. The test method includes the following.

In a first period, first switches and second switches are controlled to be turned on, a lighting voltage is input to a test signal line electrically connected to second ends of switches electrically connected to corresponding pixel units in odd columns, and an extinction voltage is input to a test signal line electrically connected to second ends of switches electrically connected to corresponding pixel units in even columns.

In some embodiments, in a second period, the first switches and the second switches are controlled to be turned on, the extinction voltage is input to the test signal line electrically connected to the second ends of the switches electrically connected to the corresponding pixel units in the odd columns, and the lighting voltage is input to the test signal line electrically connected to the second ends of the switches electrically connected to the corresponding pixel units in the even columns.

### BRIEF DESCRIPTION OF DRAWINGS

FIG. 1 is a partial structure diagram of a display panel in the related art.

FIG. 2 is a partial structure diagram of a display panel according to one or more embodiments of the present application.

FIG. 3 is a partially enlarged structure diagram of a display panel according to one or more embodiments of the present application.

FIG. 4 is a partially enlarged structure diagram of another display panel according to one or more embodiments of the present application.

FIG. 5 is a partially enlarged structure diagram of another display panel according to one or more embodiments of the present application.

FIG. 6 is a partially enlarged structure diagram of another display panel according to one or more embodiments of the present application.

FIG. 7 is a structure diagram of pads according to one or more embodiments of the present application.

FIG. 8 is a partially enlarged structure diagram of another display panel according to one or more embodiments of the present application.

FIG. 9 is a partially enlarged structure diagram of another display panel according to one or more embodiments of the present application.

FIG. 10 is a partially enlarged structure diagram of another display panel according to one or more embodiments of the present application.

FIG. 11 is a partially enlarged structure diagram of another display panel according to one or more embodiments of the present application.

FIG. 12 is a partial section view of a display panel according to one or more embodiments of the present application.

FIG. 13 is a structure diagram of another display panel according to one or more embodiments of the present application.

FIG. 14 is a structure diagram of a display device according to one or more embodiments of the present application.

FIG. 15 is a flowchart of a test method of a display panel according to one or more embodiments of the present application.

### DETAILED DESCRIPTION

When a display panel employs a fanout-in-active-area (FIAA) structure to reduce the bezel size of the display panel, disorder of the fan-out lines within the display area of the display panel may occur, which makes it difficult to detect defective display panels. Consequently, defective display panels may be missed during inspection, resulting in waste in subsequent manufacturing processes.

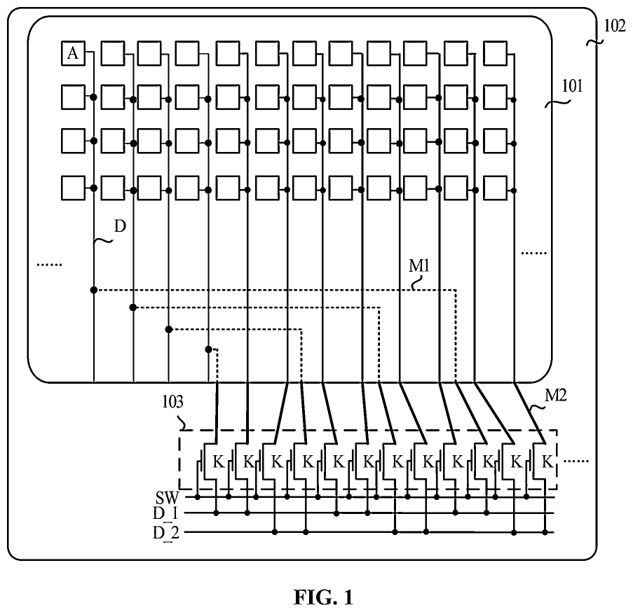

FIG. 1 is a partial structure diagram of a display panel in the related art. As shown in FIG. 1, the display panel includes an active area 101 and a non-active area 102. Pixels A, data lines D, and connection lines M1 are disposed in the active area 101. One data line, D is electrically connected to pixels A in one column. Part of the data lines D are connected to fan-out lines M2 in the non-active area 102 through connection lines M1. Part of the data lines D are directly connected to the fan-out lines M2. That is, when the display panel employs an FIAA structure to reduce the bezel size of the display panel, the arrangement sequence of the fan-out lines M2 in the non-active area 102 of the display panel is different from the arrangement sequence of the data lines D, which is equivalent to that the fan-out lines M2 in the non-active area 102 are out of order. The non-active area 102 is further provided with a detection circuit 103. The detection circuit 103 includes multiple switches K, each of which is connected to a data line D through a fan-out line M2. The display panel further includes a control line SW, a first detection line D_1, and a second detection line D_2. In the related art, two adjacent switches K are alternately connected to the first detection line D_1 and the second detection line D_2. In the detection process of the display panel, the first detection line D_1 and the second detection line D_2 may be provided with different voltages. When the fan-out lines M2 in the non-active region 102 are arranged in a disordered manner, the display panel cannot present a detection image in which pixel units are lit up in every other column even when the display panel is functioning normally, making it difficult to detect whether the display panel is defective.

Exemplarily, the fan-out lines M2 in the non-active region 102 are arranged in a disordered manner. In this case, in the row direction, the first switch K is connected to the fourth data line D through the first fan-out line M2, the second switch K is connected to the fifth data line D through the second fan-out line M2, the third switch K is connected to the sixth data line D through the third fan-out line M2, the fourth switch K is connected to the third data line D through the fourth fan-out line M2, the fifth switch K is connected to the seventh data line D through the fifth fan-out line M2, the sixth switch K is connected to the eighth data line D through the sixth fan-out line M2, the seventh switch K is connected to the second data line D through the seventh fan-out line M2, the eighth switch K is connected to the ninth data line D through the eighth fan-out line M2, the ninth switch K is connected to the tenth data line D through the ninth fan-out line M2, the tenth switch K is connected to the first data line D through the tenth fan-out line M2, the eleventh switch K is connected to the eleventh data line D through the eleventh fan-out line M2, and the twelfth switch K is connected to the twelfth data line D through the twelfth fan-out line M2. In the detection of the display panel, the control line SW may be set to provide a low level, for example, −7.5 V; the first detection line D_1 is set to provide a lighting voltage, for example, 4 V; and the second detection line D_2 is set to provide an extinction voltage, for example, 7.5 V. In this case, pixels corresponding to data lines D connected to the first switch K, the second switch K, the fifth switch K, the sixth switch K, the ninth switch K, and the tenth switch K respectively are lit up; that is, pixels corresponding to the fourth data line D, the fifth data line D, the seventh data line D, the eighth data line D, the tenth data line D, and the first data line D are lit up. Pixels corresponding to data lines D connected to the third switch K, the fourth switch K, the seventh switch K, the eighth switch K, the eleventh switch K, and the twelfth switch K respectively are extinct; that is, pixels corresponding to the sixth data line D, the third data line D, the second data line D, the ninth data line D, the eleventh data line D, and the twelfth data line D are extinct. Even when the display panel is functioning normally, it is impossible to present a detection image in which pixels A in every pair of columns are alternately lit up and lit off, for example pixels A in the first and second columns are lit up, pixels A in the third and fourth columns) are off, pixels A in fifth and sixth columns are lit up, and so forth. Therefore, it is difficult to determine whether the display panel is abnormal based on the detection image.

When the display panel adopts an FIAA structure to reduce the bezel size of the display panel, the arrangement sequence of the fan-out lines in the non-active area of the display panel is different from the arrangement sequence of the data lines, resulting in a disordered configuration of the fan-out lines in the non-active area are arranged in a disordered manner. In this case, when using a detection circuit provided by the related art for inspection, the display panel is still unable to present a detection image in which pixel units are lit up in every other column, even when there is no defect in the display panel. As a result, defective display panels cannot be effectively detected, which may lead to defective panels entering subsequent manufacturing processes and causing material waste.

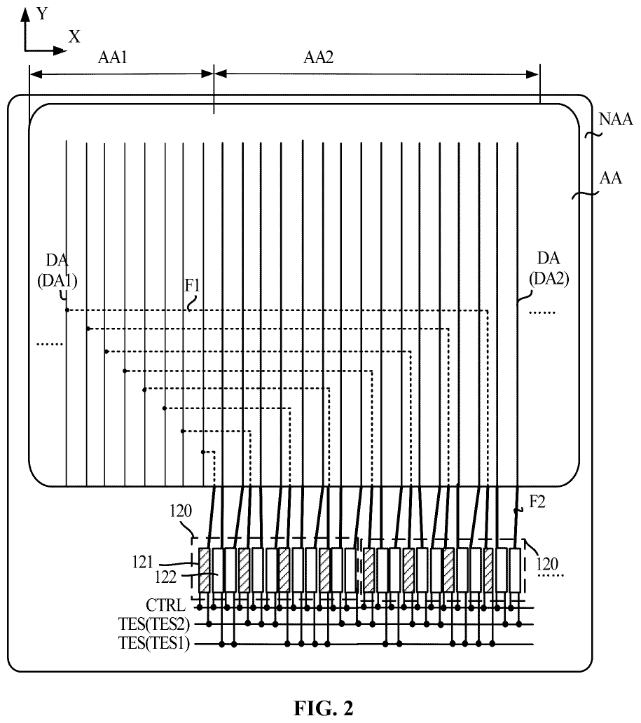

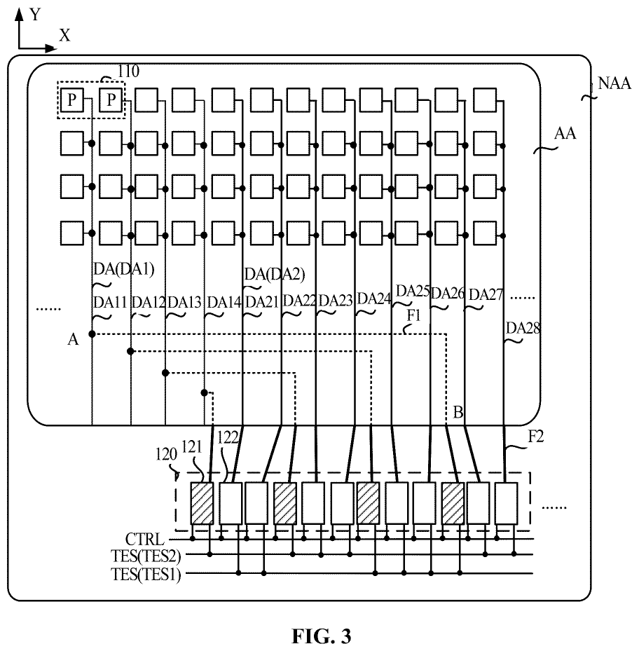

Embodiments of the present application provide a display panel. FIG. 2 is a partial structure diagram of a display panel according to one or more embodiments of the present application. FIG. 3 is a partially enlarged structure diagram of a display panel according to one or more embodiments of the present application. As shown in FIGS. 2 and 3, the display panel includes an active area AA and a non-active area NAA. The display panel further includes a plurality of pixel units 110, a plurality of data lines DA, a plurality of first fan-out lines F1, a plurality of second fan-out lines F2, a plurality of test circuit units 120, and at least two test signal lines TES.

The plurality of pixel units 110 are arranged in an array and located in the active area AA. Exemplarily, any pixel unit 110 includes at least two sub-pixels P.

The plurality of data lines DA are located in the active area AA. The plurality of data lines DA are electrically connected to pixel units 110 in corresponding columns. The plurality of data lines DA extend in the column direction Y and are arranged in the row direction X. The plurality of data lines DA include at least two first data lines DA1 (for example, DA11 to DA14) and at least two second data lines DA2 (for example, DA21 to DA28). The column direction Y may intersect the row direction X. Exemplarily, the column direction Y may be perpendicular to the row direction X.

The plurality of first fan-out lines F1 are located in the active area AA. The plurality of first fan-out lines F1 are electrically connected to corresponding first data lines DAL.

The plurality of second fan-out lines F2, the plurality of test circuit units 120, and the at least two test signal lines TES are located in the non-active area NAA. Each test circuit unit 120 includes a plurality of switches, and the plurality of switches include a plurality of first switches 121 and a plurality of second switches 122. First ends of the plurality of first switches 121 are electrically connected to corresponding first fan-out lines F1 through corresponding second fan-out lines F2. First ends of the plurality of second switches 122 are electrically connected to corresponding second data lines DA2 through corresponding second fan-out lines F2. Second ends of switches electrically connected to corresponding pixel units 110 in the same column are electrically connected to the same test signal line TES. Second ends of switches electrically connected to corresponding pixel units 110 in two adjacent columns are electrically connected to different test signal lines TES.

Exemplarily, at least two sub-pixels in the same pixel unit 110 may be located in different columns. Exemplarily, all sub-pixels in the same pixel unit 110 are located in different columns and the same row and are adjacent to each other. Exemplarily, when the pixel arrangement of the display panel is in an RGBG arrangement manner, red sub-pixels and blue sub-pixels are disposed in the same column and serve as a first column of sub-pixels. Green sub-pixels are disposed in the same column and serve as a second column of sub-pixels. First columns of sub-pixels and second columns of sub-pixels are disposed alternately. In two adjacent first columns of sub-pixels, arrangement sequences of red sub-pixels and blue sub-pixels are different. In this case, a pixel unit 110 may include sub-pixels in the same row and adjacent columns, for example, a red sub-pixel and a green sub-pixel that are located in the same row and connected to two data lines DA separately, or a blue sub-pixel and a green sub-pixel that are located in the same row and connected to two data lines DA respectively. When the pixel arrangement of the display panel is in an RGB arrangement manner, red sub-pixels are located in one column, blue sub-pixels are located in one column, and green sub-pixels are located in one column; and sub-pixel columns of different colors are disposed alternately. In this case, a pixel unit 110 may include three sub-pixels in the same row and adjacent columns, which are a red sub-pixel, a blue sub-pixel, and a green sub-pixel and are connected to three data lines DA respectively.

The active area AA is also provided with the first fan-out lines F1 connected to corresponding first data lines DAL. The non-active area NAA is provided with the second fan-out lines F2 and the test circuit units 120. A first end of a first switch 121 in the test circuit units 120 is connected to one end of a corresponding second fan-out line F2, and the other end of the corresponding second fan-out line F2 is connected to a corresponding first fan-out line F1. In this case, the first end of the first switch 121 is connected to a corresponding first data line DA1 through the corresponding second fan-out line F2 and the corresponding first fan-out line F1, which is used for supplying test signals to corresponding sub-pixels connected to the first data line DAL. A first end of a second switch 122 in the test circuit units 120 is connected to one end of a corresponding second fan-out line F2, and the other end of the corresponding second fan-out line F2 is connected to a corresponding second data line DA2, which is used for supplying test signals to corresponding sub-pixels connected to the second data line DA2. To reduce the size of the lower bezel, when the first fan-out lines F1 are disposed in the active area AA, one end of each first fan-out line F1 is electrically connected to a first data line DA1, and the other end is inserted between two second data lines DA2 and extends from the active area AA to the non-active area NAA. Therefore, the arrangement sequence of the second fan-out lines F2 of the display panel is different from the arrangement sequence of corresponding data lines connected to the second fan-out lines F2, and the second fan-out lines F2 are arranged in a disordered manner. Exemplarily, with continued reference to FIG. 3, the first data lines DA1 and the second data lines DA2 may be arranged sequentially in the row direction X. FIG. 3 exemplarily illustrates a corresponding group of data lines DA connected to one test circuit unit 120. Four first data lines DA1 are provided, which may be the first first data line DA11, the second first data line DA12, the third first data line DA13, and the fourth first data line DA14 in sequence. Eight second data lines DA2 are provided, which may be the first second data line DA21, the second second data line DA22, the third second data line DA23, the fourth second data line DA24, the fifth second data line DA25, the sixth second data line DA26, the seventh second data line DA27, and the eighth second data line DA28 in sequence. The first data line to the twelfth data line from left to right in the row direction X are the first first data line DA11, the second first data line DA12, the third first data line DA13, the fourth first data line DA11, the first second data line DA21, the second second data line DA22, the third second data line DA23, the fourth second data line DA24, the fifth second data line DA25, the sixth second data line DA26, the seventh second data line DA27, and the eighth second data line DA28 in sequence. Four first fan-out lines F1 and twelve second fan-out lines F2 are connected to the corresponding test circuit unit 120. Each first fan-out line F1 may be electrically connected to one first data line DAL. Each second fan-out line F2 may be electrically connected to one first fan-out line F1 or one second data line DA2. Exemplarily, for the four first fan-out lines F1 and the twelve second fan-out lines F2 corresponding to the test circuit unit 120, the first first fan-out line F1 to the fourth first fan-out line F1 are arranged according to the direction from left to right in FIG. 3, and the first second fan-out line F2 to the twelfth second fan-out line F2 are arranged according to the direction from left to right in FIG. 3. In this case, the first second fan-out line F2 may be configured to be electrically connected to the fourth first data line DA14 (the fourth data line on the left) through the first first fan-out line F1, equivalent to that the leftmost second fan-out line F2 is not electrically connected to the leftmost data line DA. That is, the arrangement sequence of the second fan-out lines F2 is different from the arrangement sequence of corresponding data lines DA electrically connected to the second fan-out lines F2. The second second fan-out line F2 and the third second fan-out line F2 are electrically connected to the first second data line DA21 (the fifth data line on the left) and the second second data line DA22 (the sixth data line on the left) respectively. The fourth second fan-out line F2 is electrically connected to the third first data line DA13 (the third data line on the left) through the second first fan-out line F1. The fifth second fan-out line F2 and the sixth second fan-out line F2 are electrically connected to the third second data line DA23 (the seventh data line on the left) and the fourth second data line DA24 (the eighth data line on the left) respectively. The seventh second fan-out line F2 is electrically connected to the second first data line DA12 (the second data line on the left) through the third first fan-out line F1. The eighth second fan-out line F2 and the ninth second fan-out line F2 are electrically connected to the fifth second data line DA25 (the ninth data line on the left) and the sixth second data line DA26 (the tenth data line on the left) respectively. The tenth second fan-out line F2 is electrically connected to the first first data line DA11 (the first data line on the left) through the fourth first fan-out line F1. The eleventh second fan-out line F2 and the twelfth second fan-out line F2 are electrically connected to the seventh second data line DA27 (the eleventh data line on the left) and the eighth second data line DA28 (the twelfth data line on the left) respectively. In this case, from left to right according to FIG. 3, the correspondence relationship between the arrangement sequence of the second fan-out lines F2 and the arrangement sequence of corresponding data lines is that the first second fan-out line F2 to the twelfth second fan-out line F2 correspond to the fourth data line, the fifth data line, the sixth data line, the third data line, the seventh data line, the eighth data line, the second data line, the ninth data line, the tenth data line, the first data line, the eleventh data line, and the twelfth data line respectively. That is, the arrangement sequence of the second fan-out lines F2 is different from the arrangement sequence of corresponding data lines electrically connected to the second fan-out lines F2, and the second fan-out lines F2 are out of order.

The number of first switches 121 is equal to the number of first data lines DAL. The number of second switches 122 is equal to the number of second data lines DA2. When a pixel unit 110 includes at least two sub-pixels P in different columns, at least two switches may be provided correspondingly for the same pixel unit 110. In pixel units electrically connected to the same test circuit unit, all sub-pixels of pixel units 110 in the same column may be electrically connected to first switches, or all sub-pixels of pixel units 110 in the same column may be electrically connected to second switches. First ends of first switches 121 are electrically connected to corresponding first fan-out lines F1 through corresponding second fan-out lines F2. First ends of second switches 122 are electrically connected to corresponding second data lines DA2 through corresponding second fan-out lines F2. When the second fan-out lines F2 are arranged in a disordered manner, switches electrically connected to corresponding pixel units 110 in the same column may include a first switch 121 and/or a second switch 122. In this case, a second end of a first switch 121 and/or a second switch 122 electrically connected to corresponding pixel units 110 in the same column is electrically connected to the same test signal line TES. Second ends of switches electrically connected to corresponding pixel units 110 in two adjacent columns are electrically connected to different test signal lines TES. In the detection of the display panel, different test signals may be supplied through different test signal lines TES so that test signals acquired by pixel units 110 in two adjacent columns are different. When the display panel is normal, the display panel can present a detection image in which pixel units 110 are lit up at intervals of X columns; for example, pixel units 110 in the detection image display a white color at intervals of X columns. When the display panel includes p test signal lines TES, x is an integer greater than or equal to 1 and less than or equal to p−1, and p is an integer greater than or equal to 2. When the display panel is abnormal, the display panel cannot present a detection image in which pixel units 110 are lit up at intervals of X columns. Therefore, whether the display panel is abnormal can be determined according to the detection image, thereby achieving the detection of defective display panels. Exemplarily, at least two second fan-out lines F2 electrically connected to corresponding pixel units 110 in the same column are disposed in different layers, at least two second fan-out lines F2 electrically connected to corresponding pixel units 110 in different columns are disposed in the same layer, with no second fan-out line F2 in the same layer disposed in between. When second fan-out lines F2 in the same layer are short-circuited, the display panel fails to present a detection image in which pixel units 110 are lit up at intervals of X columns; for example, the display panel presents a detection image in which pixel units 110 in two adjacent columns are lit up simultaneously, and the brightness of pixel units 110 in at least two adjacent columns is between the maximum brightness and extinction, thereby achieving the detection of the defective display panel based on the detection image.

Exemplarily, the number of sub-pixels in each of the pixel units 110 in the same column is equal. Exemplarily, the number of sub-pixels in each of the pixel units 110 in different columns is equal or unequal. Exemplarily, referring to FIG. 3, when a pixel unit 110 includes two sub-pixels P and the two different sub-pixels P are disposed in different columns, the display panel may include fourth first data lines DA1 and eight second data lines DA2. The connection relationship with the second fan-out lines F2 is shown in FIG. 3. In this case, two sub-pixels P in each pixel unit 110 in the first column may be correspondingly connected to the first first data line DA11 and the second first data line DA12. Two sub-pixels P in each pixel unit 110 in the second column may be correspondingly connected to the third first data line DA13 and the fourth first data line DA14. Two sub-pixels P in each pixel unit 110 in the third column may be correspondingly connected to the first second data line DA21 and the second second data line DA22. Two sub-pixels P in each pixel unit 110 in the fourth column may be correspondingly connected to the third second data line DA23 and the fourth second data line DA24. Two sub-pixels P in each pixel unit 110 in the fifth column may be correspondingly connected to the fifth second data line DA25 and the sixth second data line DA26. Two sub-pixels P in each pixel unit 110 in the sixth column may be correspondingly connected to the seventh second data line DA27 and the eighth second data line DA28. When two test signal lines TES are included, it may be determined according to the correspondence relationship between the data lines and the second fan-out lines F2 that second ends of switches electrically connected to pixel units 110 in the first column, pixel units 110 in the third column, pixel units 110 in the fifth column, and pixel units 110 in the seventh column are electrically connected to one test signal line TES and that second ends of switches electrically connected to pixel units 110 in the second column, pixel units 110 in the fourth column, pixel units 110 in the sixth column, and pixel units 110 in the eighth column are electrically connected to the other test signal line TES. Therefore, sub-pixels P in pixel units 110 in adjacent columns may acquire different test signals. When the display panel is normal, the display panel can realize a detection image in which pixel units 110 are lit up in every other column; for example, in the detection image, pixel units 110 in one of two adjacent columns may be lit up, and pixel units 110 in the other one of two adjacent columns may be not lit up, that is, may be extinct. Exemplarily, the light emitted by multiple sub-pixels in each pixel unit may be mixed as white light, and a detection image of the multiple sub-pixels may be a white image. Moreover, two second fan-out lines F2 connected to corresponding pixel units 110 in the same column may be disposed in different layers, two second fan-out lines F2 in four second fan-out lines F2 connected to corresponding pixel units 110 in two adjacent columns may be disposed in the same layer, and two other second fan-out lines F2 in the four second fan-out lines F2 may be disposed in the same layer. For example, two second fan-out lines F2 connected to corresponding pixel units 110 in the first column are disposed in two conductive layers respectively. The first second fan-out line F2 connected to corresponding pixel units 110 in the second column and the first second fan-out line F2 connected to corresponding pixel units 110 in the first column are disposed in the same conductive layer. The second second fan-out line F2 connected to corresponding pixel units 110 in the second column and the second second fan-out line F2 connected to corresponding pixel units 110 in the first column are disposed in the same conductive layer. When second fan-out lines F2 in the same layer are short-circuited, the display panel fails to present a detection image in which pixel units 110 in two adjacent columns are lit up in every other column. Therefore, whether the display panel is abnormal can be determined according to the detection image, thereby achieving the short-circuit detection of the display panel.

For the solution in embodiments of present application, first ends of first switches in a test circuit unit are electrically connected to corresponding first fan-out lines through corresponding second fan-out lines; first ends of second switches are electrically connected to corresponding second data lines through corresponding second fan-out lines; second ends of switches electrically connected to corresponding pixel units in the same column are electrically connected to the same test signal line; and second ends of switches electrically connected to corresponding pixel units in two adjacent columns are electrically connected to different test signal lines. With this arrangement, in the detection of the display panel, different test signals may be supplied through different test signal lines so that test signals acquired by pixel units in two adjacent columns are different. When the display panel is normal, the display panel can present a detection image in which pixel units spaced at least one column apart are lit up. When the display panel is abnormal, the display panel fails to present a detection image in which pixel units spaced at least one column apart are lit up. Therefore, whether the display panel is abnormal can be determined according to the detection image, thereby achieving the detection of the defective display panel based on the detection image.

With continued reference to FIG. 3, the at least two test signal lines TES include a first test signal line TES1 and a second test signal line TES2. Second ends of switches electrically connected to corresponding pixel units in odd columns are electrically connected to the first test signal line TES1. Second ends of switches electrically connected to corresponding pixel units 110 in even columns are electrically connected to the second test signal line TES2.

In the detection of the display panel, one of the first test signal line TES1 and the second test signal line TES2 may be used for inputting the lighting voltage, and the other one may be used for inputting the extinction voltage. When the display panel is normal, the display panel can present a detection image in which pixel units 110 in each two adjacent columns spaced one column apart are lit up. When the display panel is abnormal, the display panel fails to present a detection image in which pixel units 110 in each two columns spaced one column apart are lit up. Therefore, whether the display panel is abnormal can be determined according to the detection image, thereby achieving the detection of the defective display panel based on the detection image.

Exemplarily, when a pixel unit 110 includes two adjacent sub-pixels P located in the same row and different columns, the display panel may include two conductive layers. The second fan-out lines F2 may be disposed alternately in the two conductive layers from left to right in the row direction X. Moreover, two second fan-out lines F2 connected to corresponding pixel units 110 in the same column may be disposed in different layers, two second fan-out lines F2 of four second fan-out lines F2 connected to corresponding pixel units 110 in two adjacent columns may be disposed in the same layer, and two other second fan-out lines F2 of the four second fan-out lines F2 may be disposed in the same layer. For example, the first second fan-out line F2 connected to corresponding pixel units 110 in an odd column and the first second fan-out line F2 connected to corresponding pixel units 110 in an even column are disposed in the same layer and has a short distance in between; for example, no second fan-out line in the same layer but only a second fan-out line in a different layer is disposed between these two first second fan-out lines F2. In the detection process of the display panel, the first test signal line TES1 may input the lighting voltage, and the second test signal line TES2 may input the extinction voltage. When second fan-out lines F2 in the same layer are short-circuited, pixel units 110 in odd columns and pixel units 110 in even columns are each input with the lighting voltage or the extinction voltage so that the display panel fails to show a detection image in which pixel units 110 in two columns spaced one column apart are lit up. Therefore, whether the display panel is abnormal can be determined according to the detection image, thereby achieving the detection of the defective display panel based on the detection image.

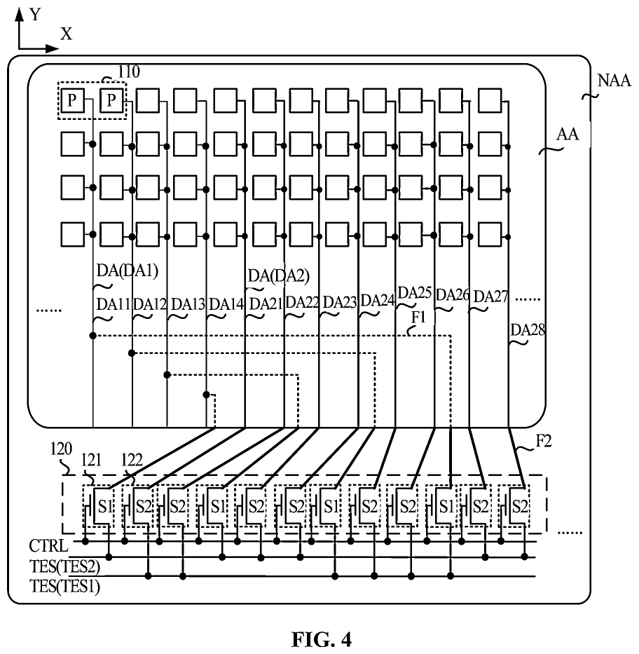

FIG. 4 is a partial enlarged structure diagram of another display panel according to one or more embodiments of the present application. As shown in FIG. 3, the display panel further includes a control signal line CTRL. Control ends of the first switches 121 and control ends of the second switches 122 are electrically connected to the control signal line CTRL.

Exemplarily, the same control signal line CTRL may supply control signals to the first switches 121 and the second switches 122. When the display panel is not under detection, a control signal provided by the control signal line CTRL may control the first switches 121 and the second switches 122 to be turned off. When the display panel is under detection, a control signal provided by the control signal line CTRL may control the first switches 121 and the second switches 122 to be turned on so that test signals provided by the test signal line TES connected to second ends of the first switches 121 and test signals provided by the test signal line TES connected to second ends of the second switches 122 are output through the first switches 121 and the second switches 122 to corresponding pixel units 110 in electrical connection respectively, thereby achieving the detection of the defective display panel based on the detection image.

With continued reference to FIG. 4, a first switch 121 includes a first transistor S1. A first electrode of the first transistor S1 serves as a first end of the first switch 121. A second electrode of the first transistor S1 serves as the second end of the first switch 121. The control end of the first transistor S1 serves as the control end of the first switch 121. In some embodiments, a second switch 122 includes a second transistor S2. A first electrode of the second transistor S2 serves as a first end of the second switch 122. A second electrode of the second transistor S2 serves as the second end of the second switch 122. The control end of the second transistor S2 serves as the control end of the second switch 122.

Exemplarily, FIG. 4 exemplarily illustrates that the first switch 121 includes the first transistor S1 and the second switch 122 includes the second transistor S2. The channel type of the first transistor S1 may be the same as the channel type of the second transistor S2. FIG. 4 merely exemplarily illustrates that the first transistor S1 and the second transistor S2 are each an N-type transistor. In other embodiments, it may also be set that the first reset transistor S1 and the second transistor S2 are each a p-type transistor. In the detection process of the display panel, the timing of control signals may be adjusted adaptively, which is not limited here.

Exemplarily, the first transistor S1 and the second transistor S2 may be each a p-type transistor. When the display panel is not under detection, a control signal provided by the control signal line CTRL may be at a high level, for example, 8.5 V, so that the first transistor S1 and the second transistor S2 are in the off state. When the display panel is under detection, the control signal provided by the control signal line CTRL may be at a low level, for example, −7.5 V, so that the first transistor S1 and the second transistor S2 are in the on state. The voltage supplied by the first test signal line TES1 is the lighting voltage, for example, 4 V. The voltage supplied by the second test signal line TES2 is the extinction voltage, for example, 7.5 V. In this case, corresponding pixel units 110 connected to the transistor connected to the first test signal line TES1 are lit up, and corresponding pixel units 110 connected to the transistor connected to the second test signal line TES2 are extinct. When the display panel is normal, the display panel can show a detection image in which pixel units 110 are lit up in every other column. When the display panel is abnormal, the display panel fails to show a detection image in which pixel units 110 in two adjacent columns are lit up in every other column. Therefore, whether the display panel is abnormal can be determined according to the detection image, thereby achieving the detection of the defective display panel based on the detection image.

On the basis of the preceding embodiments, the arrangement sequence of the plurality of second fan-out lines F2 in the row direction X is different from the arrangement sequence of corresponding data lines DA electrically connected to the second fan-out lines F2.

Exemplarily, the arrangement sequence of the data lines DA in the positive direction of the row direction X is the overall arrangement sequence of the first data lines DA1 and second data lines DA2 in the row direction X. When the arrangement sequence of the plurality of second fan-out lines F2 in the positive direction of the row direction X is different from the arrangement sequence of corresponding data lines DA electrically connected to the second fan-out lines F2, the second fan-out lines F2 are out of order. When the active area AA has filleted corner areas on both sides of one end of the active area AA facing the test circuit unit 120, second fan-out lines F2 corresponding to pixel units 110 in corresponding columns in the filleted corner areas may be moved to a middle area of the display panel and then are connected through first fan-out lines F1 to data lines DA corresponding to the pixel units 110. Therefore, the second fan-out lines F2 can be prevented from being disposed in the filleted corner area, reducing the width of the non-active area NAA.

In other embodiments, exemplarily, first ends of first fan-out lines F1 electrically connected to second fan-out lines F2 are closer to a second data line DA2 located in the middle of the active area AA compared with second ends of first fan-out lines F1 electrically connected to first data lines F1.

With this arrangement, compared with a driver chip that connects all the data lines DA to a bonding area through the fan-out lines in the non-active area NAA, the first data lines DA1 at an edge of the active area AA are led out from the middle of the active area AA through the first fan-out lines F1, reducing the space occupied by fan-out lines in the non-active area NAA and helping achieve a narrow bezel. Exemplarily, the first first data line DA11 is connected to the fourth first fan-out line F1, the fourth first fan-out line F1 is correspondingly connected to the tenth second fan-out line F2. Compared with a second end A of the fourth first fan-out line F1 electrically connected to the first first data line DA11, a first end B of the fourth first fan-out line F1 electrically connected to the tenth second fan-out line F2 is closer to the second data line DA2 in the middle of the active area AA so that a second fan-out line F2 corresponding to the first first data line DA11 is closer to a middle area of the non-active area NAA, thereby reducing the width of the non-active area NAA.

In other embodiments, exemplarily, the plurality of second fan-out lines F2 may also be arranged in the row direction X. Exemplarily, an outermost second fan-out line F2 is electrically connected to a first end of a first switch 121. Exemplarily, an outermost second fan-out line F2 is electrically connected to a first end of a second switch 122.

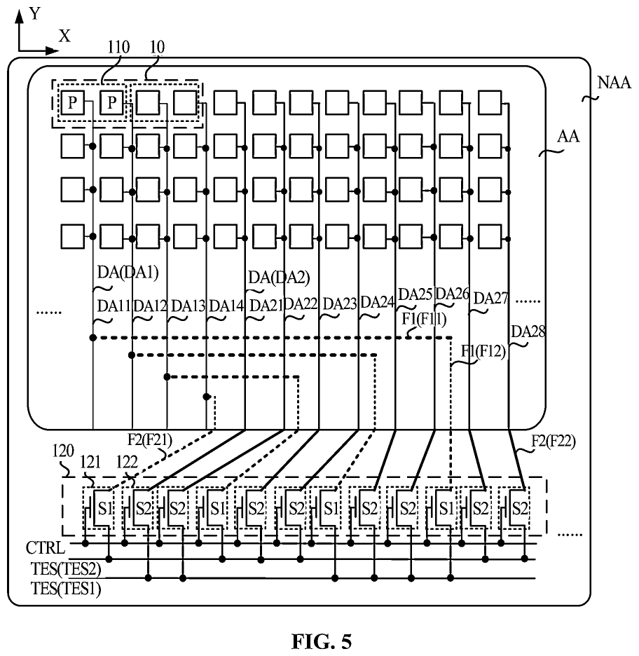

FIG. 5 is a partial enlarged structure diagram of another display panel according to one or more embodiments of the present application. As shown in FIG. 5, each first fan-out line F1 includes a first connection line F11 and a second connection line F12 that are electrically connected to each other. The second connection line F12 is electrically connected to a corresponding first data line DA1 through the first connection line F11. A plurality of second connection lines F2 of the plurality of first fan-out lines extend in the column direction Y and are arranged in the row direction X.

Exemplarily, in multiple second connection lines F12 electrically connected to the same test circuit unit 120, N data lines DA are disposed between two adjacent second connection lines F12, where N is an integer greater than or equal to 2. This is equivalent to that in multiple second connection lines F12 electrically connected to the same test circuit unit 12, one second connection line F12 is inserted every N data lines DA. Exemplarily, in multiple second connection lines F12 electrically connected to the same test circuit unit 120, N data lines DA between two adjacent second connection lines F12 are N second data lines DA2. N second data lines DA2 disposed between two adjacent second connection lines F12 are electrically connected to corresponding pixel units in the same column. In 2N second data lines DA2 disposed between three adjacent second connection lines F12, N data lines DA of the 2N second data lines DA2 and other N data lines DA of the 2N second data lines DA2 are electrically connected to corresponding pixel units in different columns, for example, pixel units in two adjacent columns. Multiple second connection lines F12 electrically connected to the same test circuit unit 120 are electrically connected to corresponding pixel units in the same column or corresponding pixel units in at least two adjacent columns.

Exemplarily, any pixel unit 110 among the plurality of pixel units 110 includes M sub-pixels P or is electrically connected to M data lines DA, where M is an integer greater than or equal to 2. Any test circuit unit 120 includes K*M first switches and N*K*M second switches, where K is an integer greater than or equal to 1.

Exemplarily, the extension direction of the first connection line F11 intersects the extension direction of the second connection line F12 so that the first fan-out line F1 has a projection in the row direction X. Exemplarily, as shown in FIG. 5, the first connection lines F11 of the first fan-out lines may extend in the row direction X. Exemplarily, a pixel unit 110 includes M sub-pixels P disposed in different columns. Exemplarily, M sub-pixels P in a pixel unit 110 are arranged in the row direction X and are electrically connected to M data lines DA respectively. In some embodiments, a pixel unit 110 includes at least two sub-pixels P arranged in M columns, the pixel unit 110 is electrically connected to M data lines DA. K*M second connection lines F12 corresponding to the same test circuit unit 120 may be included and are connected to data lines DA corresponding to K pixel circuits 110 respectively. In this case, the data lines DA corresponding to the K pixel circuits 110 may be first data lines DA1. A second connection line F12 is inserted between different second data lines DA2, and N second data lines DA2 may be disposed between two adjacent second connection lines F12. When K*M second connection lines F12 corresponding to the same test circuit unit 120 are included, K*M*(N+1) second fan-out lines F2 may be set to correspond to the same test circuit unit 120 and are used for supplying test signals for corresponding second connection lines F12 and data lines DA between the corresponding second connection lines D12. Moreover, any test circuit unit 120 may include K*M first switches and N*K*M second switches. Each of the K*M first switches is electrically connected to a first fan-out line F1 through a second fan-out line F2 to supply test signals to a first data line DA1 corresponding to the first fan-out line F1. The number and arrangement manner of first switches 121 and second switches 122 in any test circuit unit 1220 are the same or similar, which is equivalent to a test circuit repetition unit. Moreover, each of the N*K*M second switches is electrically connected to a second data line DA2 through a second fan-out line F2 to supply test signals to the second data line DA2 corresponding to the second fan-out line F2. In an arrangement where second ends of switches electrically connected to corresponding pixel units 110 in the same column are electrically connected to the same test signal line TES and second ends of switches electrically connected to corresponding pixel units 110 in two adjacent columns are electrically connected to different test signal lines TES, different test signals may be supplied to different test signal lines TES in the detection process of the display panel so that test signals acquired by pixel units 110 in two adjacent columns are different. When the display panel is normal, the display panel can show a detection image in which pixel units 110 are lit up at intervals of X columns, where the display panel includes p test signal lines TES, and x is an integer greater than or equal to 1 and less than or equal to p−1. When the display panel is abnormal, the display panel fails to show a detection image in which pixel units 110 are lit up at intervals of X columns. Therefore, whether the display panel is abnormal can be determined according to the detection image, thereby achieving the detection of the defective display panel based on the detection image.

Exemplarily, when each of M, N, and K is 2, each pixel unit 120 is electrically connected to two data lines DA, and two data lines DA are disposed between two adjacent second connection lines F12. A pixel repetition unit 10 includes two pixel units 110. In this case, four first fan-out lines F1 may be correspondingly set for a same test circuit unit 120, that is, four second connection lines F12 are included, and twelve second fan-out lines F2 are provided correspondingly for a same test circuit unit 120. Moreover, a test circuit unit 120 may include four first switches 121 and eight second switches 122. Each of the four first switches 121 is electrically connected to a first fan-out line F1 through a second fan-out line F2 to supply test signals to a first data line DA1 corresponding to the first fan-out line F1. Moreover, each of the eight second switches 122 is electrically connected to a second data line DA2 through a second fan-out line F2 to supply test signals to the second data line DA2 corresponding to the second fan-out line F2. When two test signal lines TES are included, second ends of switches electrically connected to corresponding pixel units 110 in the same column are electrically connected to the same test signal line TES, and second ends of switches electrically connected to corresponding pixel units 110 in two adjacent columns are electrically connected to different test signal lines TES. In this case, different test signals may be supplied to different test signal lines TES in the detection process of the display panel so that test signals acquired by pixel units 110 in two adjacent columns are different. When the display panel is normal, the display panel can present a detection image in which pixel units 110 are lit up in every other column. When the display panel is abnormal, the display panel fails to show a detection image in which pixel units 110 are lit up in every other column. Therefore, whether the display panel is abnormal can be determined according to the detection image, thereby achieving the detection of the defective display panel based on the detection image.

With continued reference to FIG. 5, the plurality of pixel units 110 are divided into at least two pixel repetition units 10, any one pixel repetition unit includes K pixel units 110. Exemplarily, when K is an integer greater than or equal to 2, any pixel repetition unit 10 may include K adjacent pixel units 110 arranged in the row direction X. K adjacent pixel units 110 in the same row may serve as one pixel repetition unit 10.

Exemplarily, a pixel repetition unit 10 may be an integer multiple of pixel units 110 arranged repeatedly. That is, a pixel repetition unit 10 includes K pixel units 110, and K is an integer greater than or equal to 1. Exemplarily, when the pixel arrangement of the display panel is in an RGBG arrangement manner, two pixel units 110 form one pixel repetition unit in the row direction X.

On the basis of the preceding embodiments, with continued reference to FIG. 5, the first connection line F11 extends in the row direction X. Exemplarily, among a plurality of first connection lines F11 arranged in the column direction Y, a corresponding first data line DA1 electrically connected to a longer first connection line 11 is closer to the bezel of the display panel, and a corresponding second connection line F12 electrically connected to the first connection line 11 is longer.

Exemplarily, the active area of the display panel may be a rounded rectangle. A first data line DA1 closer to the bezel of the display panel is shorter and is connected to a longer first connection line F11 and a longer second connection line F12, helping reduce the impedance difference of circuits. With this arrangement, a first connection line F11 is prevented from intersecting a second connection line F12 not electrically connected to the first connection line F11, helping simplify the arrangement of the first fan-out lines F1.

With continued reference to FIG. 5, the plurality of second fan-out lines F2 include at least two third fan-out lines F21 and at least two fourth fan-out lines F22. The third fan-out lines F21 are electrically connected to first ends of first switches 121 respectively. The fourth fan-out lines F22 are electrically connected to first ends of second switches 122.

Exemplarily, the at least two third fan-out lines F21 may be electrically connected to the first data lines DA1 through the first fan-out lines F1 respectively. Moreover, the third fan-out lines F21 are electrically connected to first ends of the first switches 121 so that when the first switches 121 are turned on, test signals are supplied to the first data lines DA1 through the third fan-out lines F21 and the first fan-out lines F1. The at least two fourth fan-out lines F22 may be electrically connected to the second data lines DA2 respectively. Moreover, the fourth fan-out lines F22 are electrically connected to first ends of the second switches 122 so that when the second switches 122 are turned on, test signals are supplied to the second data lines DA2 through the fourth fan-out lines F22. When the display panel uses an FIAA structure, the arrangement sequence of the third fan-out lines F21 is different from the arrangement sequence of the corresponding first data lines DA1 electrically connected to the third fan-out lines F21 in the row direction X. In this case, drive signals may be supplied to the third fan-out lines F21 through a reverse-sequence channel of a reverse-sequence driver chip. Moreover, the reverse-sequence driver chip may also include a positive-sequence channel through which drive signals may be supplied to the fourth fan-out lines F22.

With continued reference to FIG. 5, the plurality of second fan-out lines F2 are arranged in the row direction X. The arrangement sequence of the third fan-out lines F21 is opposite to the arrangement sequence of the corresponding first data lines DA1 electrically connected to the third fan-out lines F21. In this case, the corresponding connection relationship between the third fan-out lines F21 and the first data lines DA1 is simplified.

Exemplarily, the arrangement sequence of the fourth fan-out lines F22 is the same as the arrangement sequence of the corresponding second data lines DA2 electrically connected to the fourth fan-out lines F22. In this case, the corresponding connection relationship between the fourth fan-out lines F22 and the second data lines DA2 is simplified.

On the basis of the preceding embodiments, exemplarily, among multiple second fan-out lines F2 electrically connected to the same test circuit unit 120, N fourth fan-out lines F22 are disposed between two adjacent third fan-out lines F21. This is equivalent to that one third fan-out line F21 is inserted for every N fourth fan-out lines F22.

Exemplarily, among multiple second fan-out lines F2 electrically connected to the same test circuit unit 120, N fourth fan-out lines F22 between two adjacent third fan-out lines F21 are electrically connected to corresponding pixel units 110 in the same column. Among 2N fourth fan-out lines F22 between three adjacent third fan-out lines F21, N fourth fan-out lines F22 and other N fourth fan-out lines F22 are electrically connected to corresponding pixel units 110 in different columns, for example, pixel units in two adjacent columns. In some embodiments, in each test circuit unit 120, the plurality of first switches 121 and the plurality of second switches 122 are arranged in the row direction X. N second switches 122 are disposed between two adjacent first switches 121.

Exemplarily, the number of third fan-out lines F21 is equal to the number of second connection lines F12, and the third fan-out lines F21 are electrically connected to the second connection lines F12 in a one-to-one manner. When K*M second connection lines F12 corresponding to the same test circuit unit 12 are included and are connected to first data lines DA1 corresponding to K pixel units 110, the third fan-out lines F21 are electrically connected to the corresponding K pixel units 110. The fourth fan-out lines F22 are electrically connected to the second data lines DA2 and are electrically connected to corresponding K*N pixel units 110. When N fourth fan-out lines F22 are disposed between two adjacent third fan-out lines F21, a repetition unit of the third fan-out lines F21 and the fourth fan-out lines F22 has K*M*(N+1) second fan-out lines F2.

When N data lines DA are disposed between two adjacent second connection lines F12, N fourth fan-out lines F22 may be disposed between two adjacent third fan-out lines F21 so that the third fan-out lines F21 may be connected to the corresponding second connection lines F12. Moreover, N fourth fan-out lines F22 between two adjacent third fan-out lines F21 are electrically connected to corresponding pixel units 110 in the same column so that N fourth fan-out lines F22 between two adjacent third fan-out lines F21 are connected to N data lines DA between corresponding two adjacent second connection lines F12, simplifying the circuit arrangement in the non-active area NAA. Moreover, N fourth fan-out lines F22 between two adjacent third fan-out lines F21 are electrically connected to corresponding pixel units 110 in the same column. Among 2N fourth fan-out lines F22 between three adjacent third fan-out lines F21, N fourth fan-out lines F22 and other N fourth fan-out lines F22 are electrically connected to corresponding pixel units 110 in different columns. In this case, K*M*(N+1) second fan-out lines F2 can be electrically connected to K pixel units 110 in the same pixel repetition unit 10. Therefore, switches in one test circuit unit 120 are electrically connected to pixel units 110 in multiple pixel repetition units 10, achieving the detection of the defective display panel.

Exemplarily, N is an integer multiple of M. N may be greater than or equal to M. The greater the N, the greater the number of second fan-out lines corresponding to one test circuit unit 120. The test circuit unit 120 serves as a circuit repetition unit. When the number of second fan-out lines corresponding to the test circuit unit 120 is greater, the cost of manpower inspection is high and the efficiency is low when the third fan-out lines and the fourth fan-out lines are sorted and inspected. The greater the N, the smaller the number of first data lines, which is not conducive to narrowing the bezel. A greater N better helps improve the probability of short-circuit detection.

Additionally, in other embodiments, it may be also set that in each test circuit unit 120, the plurality of first switches 121 and the plurality of second switches 122 are arranged in the row direction X. N second switches 122 are disposed between two adjacent first switches 121. In this case, the first switches 121 may be electrically connected to corresponding third fan-out lines F21 in sequence, and the second switches 122 may be electrically connected to corresponding fourth fan-out lines F22 in sequence, thereby further simplifying the wiring design of the non-active area NAA.

On the basis of the preceding embodiments, exemplarily, in each test circuit unit 120, second ends of N second switches 122 between two adjacent first switches 121 are electrically connected to the same test signal line TES. Among 2N second switches 122 between three adjacent first switches 121, a test signal line TES electrically connected to second ends of N second switches 122 is different a test signal line TES electrically connected to second ends of N other switches 122.

Exemplarily, when second ends of N second switches 122 between two adjacent first switches 121 are electrically connected to the same test signal line TES, second ends of switches electrically connected to corresponding pixel units 110 in the same column can be electrically connected to the same test signal line TES when second ends of N second switches 122 between two adjacent first switches 121 are electrically connected to corresponding pixel units 110 in the same column. Among 2N second switches 122 between three adjacent first switches 121, second ends of N second switches 122 and second ends of N other switches 122 are electrically connected to different test signal lines TES. Among 2N fourth fan-out lines F22 between three adjacent third fan-out lines F21, when N fourth fan-out lines F22 are electrically connected to pixel units 110 in a first column, the other N fourth fan-out lines F22 are electrically connected to pixel units 110 in a second column different from the first column, second ends of switches electrically connected to corresponding pixel units 110 in two adjacent columns are electrically connected to different test signal lines TES, so that the display panel can achieve the detection in which pixel units are lit up in every other column in the column direction Y.

On the basis of the preceding embodiments, the plurality of first switches in each test circuit unit are electrically connected to corresponding pixel units in a column or corresponding pixel units in at least two adjacent columns. The plurality of second switches in each test circuit unit are electrically connected to corresponding pixel units in multiple adjacent columns.

Exemplarily, a test circuit unit includes K*M first switches and N*K*M second switches. When K is 1, a test circuit unit may include M first switches and N*M second switches. In this case, the M first switches may be electrically connected to corresponding pixel units in one column, and the N*M second switches may be electrically connected to corresponding pixel units in N adjacent columns. When K is greater than 1, a test circuit unit may include K*M first switches and K*N*M second switches. In this case, the K*M first switches may be electrically connected to corresponding pixel units in K adjacent columns, and the K*N*M second switches may be electrically connected to corresponding pixel units in K*N adjacent columns. Moreover, N data lines are disposed between two adjacent second connection lines F12 so that pixel units electrically connected to corresponding first switches 121 are adjacent to each other and pixel units electrically connected to corresponding second switches are adjacent to each other. In this case, a test circuit unit may be electrically connected to at least part of the pixel units in K*(N+1) adjacent columns. When the arrangement sequence of the second fan-out lines is different from the arrangement sequence of corresponding data lines connected to the second fan-out lines, the circuit arrangement between test circuits and corresponding pixel units electrically connected to the test circuits is simplified.

Exemplarily, M is equal to N.

Exemplarily, when the pixel units are electrically connected to M data lines, K*M second connection lines may be set to correspond to the same test circuit unit 120 and used for being electrically connected to data lines corresponding to pixel units in K columns. Moreover, M data lines may be disposed between two adjacent second connection lines so that data lines between two adjacent second connection lines may be electrically connected to corresponding pixel units in the same column. When the arrangement sequence of the second fan-out lines is different from the arrangement sequence of corresponding data lines connected to the second fan-out lines, the wiring design between these corresponding data lines and the second fan-out lines electrically connected to these corresponding data lines is simplified.

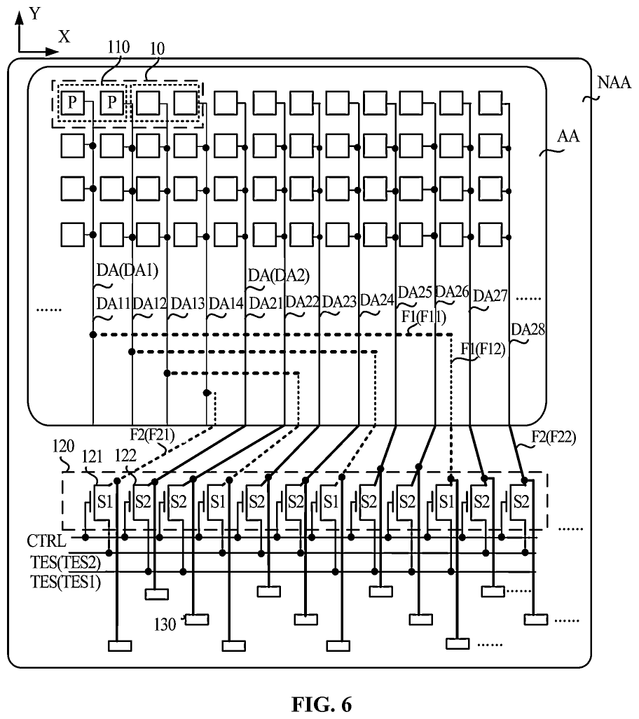

FIG. 6 is a partial enlarged structure diagram of another display panel according to one or more embodiments of the present application. As shown in FIG. 6, the display panel further includes pads 130 in N+1 rows. The pads 130 in N+1 rows are located in the non-active area NAA. Pads 130 in each row include a plurality of pads 130 arranged in the row direction X. Pads 130 in one row are electrically connected to third fan-out lines F21 electrically connected to first switches 121. The arrangement sequence of the pads 130 in the row is opposite to the arrangement sequence of corresponding data lines DA electrically connected to the pads 130 in the row. Pads 130 in other N rows are electrically connected to fourth fan-out lines F22 electrically connected to second switches 122. The arrangement sequence of the pads 130 in the other N rows is the same as the arrangement sequence of corresponding data lines DA electrically connected to the pads 130 in the other N rows.

Exemplarily, pads 130 are disposed in the non-active area NAA and are used for receiving externally input drive signals and transmitting the drive signals to the data lines DA through the first fan-out lines F1 and the second fan-out lines F2 to supply drive signals to the pixel units 110 electrically connected to the data lines DA, achieving the driving of the display panel. The arrangement sequence of the pads 130 may be set according to the sequence of ports the driver chip supplying drive signals. Exemplarily, in the row direction X, when the arrangement sequence of ports of the driver chip connected to corresponding pads 130 in one row is positive, the arrangement sequence of pads 130 in one row is positive and is the same as the arrangement sequence of corresponding data lines DA electrically connected to the pads 130. When the arrangement sequence of ports of the driver chip connected to corresponding pads 130 in one row is reverse, the arrangement sequence of pads 130 in one row is reverse and is opposite to the arrangement sequence of corresponding data lines DA electrically connected to the pads 130. For example, in the row direction X, positive-sequence ports in one row are sequentially numbered as odd ports and may be 361, 363, 365, 367, . . . , and the like which are increased sequentially; positive-sequence ports in another row are sequentially numbered as even ports and may be 362, 364, 366, 368, . . . , and the like which are increased sequentially. In this case, pads corresponding to positive-sequence ports in these two rows are arranged in the positive sequence. Reverse-sequence ports are sequentially numbered as 360, 359, 358, 357, . . . , and the like which are decreased sequentially; and the sequence number of a pad 130 is consistent with the data number of a port.

The arrangement sequence of the third fan-out lines F21 is opposite to the arrangement sequence of the corresponding first data lines DA1 electrically connected to the third fan-out lines F21. Moreover, the third fan-out lines F21 are electrically connected to first ends of the first switches 121. In this case, pads 130 in one row are set to be electrically connected to the third fan-out lines F21 electrically connected to the first switches 121 and have an arrangement sequence opposite to the arrangement sequence of corresponding data lines DA electrically connected to the third fan-out lines F21 so that the arrangement sequence of the pads 130 in this row is the same as the arrangement sequence of the third fan-out lines F21, helping simplify the connection between the pads 130 and the third fan-out lines F21 and simplify the port arrangement of the driver chip for supplying drive signals. Similarly, the arrangement sequence of the fourth fan-out lines F22 is same as the arrangement sequence of the corresponding second data lines DA2 electrically connected to the fourth fan-out lines F22. Moreover, the fourth fan-out line F22 are electrically connected to first ends of the second switches 122. In this case, pads 130 in N rows are set to be electrically connected to the fourth fan-out lines F22 electrically connected to the second switches 122 and have an arrangement sequence the same as the arrangement sequence of corresponding data lines DA electrically connected to the fourth fan-out lines F22 so that the arrangement sequence of the pads 130 in the N rows is the same as the arrangement sequence of the fourth fan-out lines F22, helping simplify the connection between the pads 130 and the fourth fan-out lines F22 and simplify the port arrangement of the driver chip for supplying drive signals.

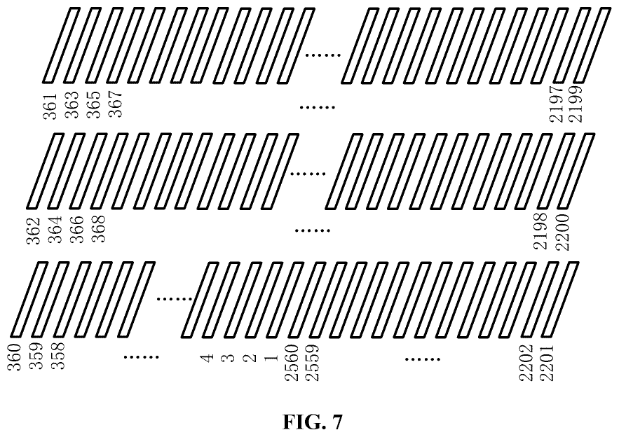

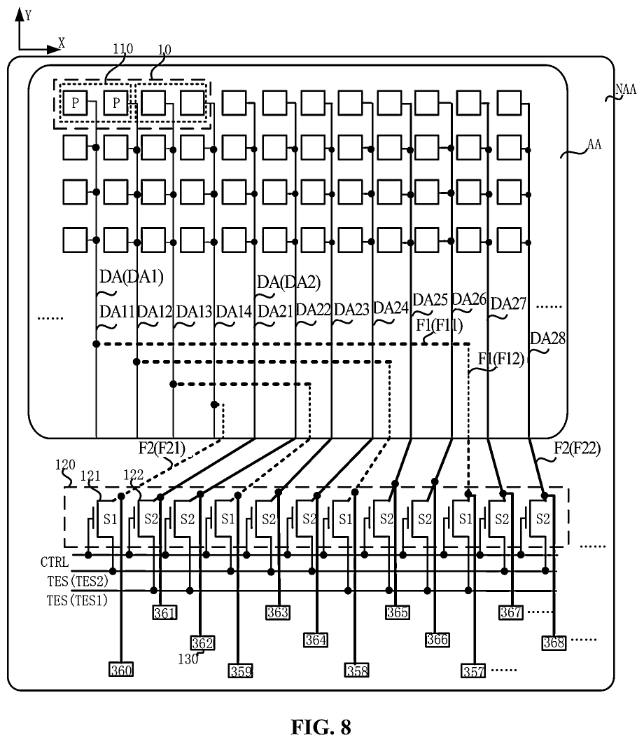

Exemplarily, FIG. 7 is a structure diagram of pads according to one or more embodiments of the present application. FIG. 8 is a partial enlarged structure diagram of another display panel according to one or more embodiments of the present application. As shown in FIGS. 7 and 8, when N is 2, two second data lines DA2 are disposed between two adjacent second connection lines F12. In this case, the display panel is provided with pads 130 in three rows, pads in one row are reverse-sequence pads, and pads in other two rows are positive-sequence pads. For example, as shown in FIG. 8, the sequence numbers of the reverse-sequence pads are 360, 359, 358, 357, . . . , and the like and are decreased sequentially. The sequence numbers of positive-sequence pads in one of the two rows are odd ports, may be 361, 363, 365, 367, . . . , and the like, and are increased sequentially. The sequence numbers of positive-sequence pads in the other of the two rows are even ports, may be 362, 364, 366, 368, . . . , and the like, and are increased sequentially. Each row exemplarily illustrates four pads 130. The reverse-sequence pads may be set to be sequentially electrically connected to the third fan-out lines F21 electrically connected to the first switches 121 so that the sequence numbers of the reverse-sequence pads are opposite to the arrangement sequence of corresponding data lines DA electrically connected to the third fan-out lines F21 to match the port arrangement of the driver chip. In this case, the driver chip can supply drive signals to the data lines electrically connected to the third fan-out lines F21. The positive-sequence pads may be set to be sequentially electrically connected to the fourth fan-out lines F22 electrically connected to the second switches 122 so that the sequence change of the positive-sequence pads is the same as the arrangement sequence of corresponding data lines DA electrically connected to the fourth fan-out lines F22 to match the port arrangement of the driver chip. In this case, the driver chip can supply drive signals to the data lines electrically connected to the fourth fan-out lines F22 to implement the display of the display panel.

With continued reference to FIGS. 2 to 6, on the basis of the preceding embodiments, when each of N, M, and K is 2, each pixel unit 120 is electrically connected to two data lines DA, and two data lines DA are disposed between two adjacent second connection lines F12. A pixel repetition unit 10 includes two adjacent pixel units 110 in the same row. A test circuit unit 120 may include four first switches 121 and eight second switches 122. Moreover, four first fan-out lines F1 and twelve second fan-out lines F2 may be correspondingly disposed for the same test circuit unit 120. Pixel units 110 in six columns electrically connected to the twelve second fan-out lines F2 are at least partially adjacent to each other. Pixel units 110 in two columns electrically connected to the four first fan-out lines F1 are adjacent to each other. Pixel units 110 in two columns electrically connected to four third fan-out lines among the twelve second fan-out lines F2 are adjacent to each other. Pixel units 110 in four columns electrically connected to eight third fan-out lines among the twelve second fan-out lines F2 are adjacent to each other. When second ends of switches electrically connected to corresponding pixel units 110 in the same column are electrically connected to the same test signal line TES and second ends of switches electrically connected to corresponding pixel units 110 in two adjacent columns are electrically connected to different test signal lines TES, different test signals may be supplied to different test signal lines TES in the detection process of the display panel so that test signals acquired by pixel units 110 in two adjacent columns are different. When the display panel is normal, the display panel can present a detection image in which pixel units 110 are lit up at intervals of X columns. When the display panel includes p test signal lines TES, x is an integer greater than or equal to 1 and less than or equal to p−1. When the display panel is abnormal, the display panel fails to present a detection image in which pixel units 110 are lit up at intervals of X columns. Therefore, whether the display panel is abnormal can be determined according to the detection image, achieving the detection of defective display panels.

Exemplarily, adjacent second fan-out lines F2 may be arranged alternately in different layers so that two second fan-out lines F2 electrically connected to corresponding pixel units 110 in the same column are disposed in different layers. Two second fan-out lines F2 among four second fan-out lines F2 electrically connected to corresponding pixel units 110 in two adjacent columns are disposed in the same layer, and other two fan-out lines F2 among the four second fan-out lines F2 are disposed in the same layer. For example, the display panel includes a first conductive layer and a second conductive layer. Three pixel repetition units 10 electrically connected to the test circuit unit 120 may be in the same row and may be adjacent to each other or partially not adjacent to each other. One pixel repetition unit 10 electrically connected to the four first switches 121 is located on one side of the active area AA relative to two pixel repetition units 10 electrically connected to the eight second switches 122. The arrangement sequence of the second fan-out lines F2 is opposite to the arrangement sequence of corresponding first data lines DA1 electrically connected to the second fan-out lines F2. The arrangement sequence of the second fan-out lines F2 is the same as the arrangement sequence of corresponding second data lines DA2 electrically connected to the second fan-out lines F2. In the same test circuit unit 120, one pixel repetition unit 10 electrically connected to four first switches 121 is in the same row as and is adjacent or not adjacent to two pixel repetition units 10 electrically connected to eight second switches 122. Exemplarily, one test circuit unit 120 may correspond to twelve second fan-out lines F2 arranged in the positive direction of the row direction X. The twelve second fan-out lines F2 are located in the first conductive layer, the second conductive layer, the first conductive layer, the second conductive layer, the first conductive layer, the second conductive layer, the first conductive layer, the second conductive layer, the first conductive layer, the second conductive layer, the first conductive layer, and the second conductive layer respectively. Second fan-out lines F2 electrically connected to corresponding pixel units 110 in the same column are disposed in different layers. Second fan-out lines F2 electrically connected to corresponding pixel units 110 in adjacent columns are at least partially disposed in the same layer and with no second fan-out line in the same layer in between so that a short circuit, when occurring, may be detected. Second fan-out lines F2 electrically connected to corresponding pixel units 110 in an odd column and second fan-out lines F2 electrically connected to corresponding pixel units 110 in an even column are at least partially disposed in the same layer and with no second fan-out line in the same layer in between so that a short circuit, when occurring, may be detected. When second ends of switches electrically connected to corresponding pixel units 110 in the same column are electrically connected to the same test signal line TES and second ends of switches electrically connected to corresponding pixel units 110 in two adjacent columns are electrically connected to another test signal line TES, different test signals may be supplied to different test signal lines TES in the detection process of the display panel so that test signals acquired by pixel units 110 in two adjacent columns are different. When the display panel is normal, the display panel can show a detection image in which alternate columns are lit up. When a short circuit occurs in second fan-out lines F2 in the same layer, pixel units 110 in two adjacent columns or not adjacent columns can be lit up simultaneously, and the brightness is between the maximum brightness and extinction, and the display panel fails to show a detection image in which pixel units are lit up in every other column, thereby achieving the detection of defective display panels.

Exemplarily, the plurality of pixel units 110 include at least two first pixel units 110A and at least two second pixel units 110B. Each first pixel unit 110A includes one first color sub-pixel P1 and one second color sub-pixel P2. Each second pixel unit 110B includes one third color sub-pixel P3 and one second color sub-pixel P2. Among pixel units 110 in the same row, first pixel units 110A and second pixel units 110B are disposed alternately in the row direction X. The first pixel unit 110A includes one first color sub-pixel P1 and one second color sub-pixel P2 that are located in different columns. The second pixel unit 110B includes one third color sub-pixel P3 and one second color sub-pixel P2 that are located in different columns.

With continued reference to FIGS. 2 to 6, the pixel units 110 may be divided into first pixel units 110A and second pixel units 110B according to colors of the sub-pixels. A first pixel unit 110A may include one first color sub-pixel P1 and one second color sub-pixel P2 that are arranged in the row direction X so that the first pixel unit 110A has sub-pixels P in two columns which are connected to two data lines DA correspondingly. A second pixel unit 110B may include one third color sub-pixel P3 and one second color sub-pixel P2 that are arranged in the row direction X so that the second pixel unit 110B has sub-pixels P in two columns which are connected to two data lines DA correspondingly. Among pixel units 110 in the same row, first pixel units 110A and second pixel units 110B are arranged alternately in the row direction X so that a first pixel unit 110A and a second pixel unit 110B that are in the same row and adjacent to each other in the row direction X form a minimum repetition unit of pixel arrangement. Additionally, pixel units 110 in two adjacent columns include first pixel units 110A and second pixel units 110B. That is, pixel units 110 in two adjacent columns both include first color sub-pixels P1, second color sub-pixels P2, and third color sub-pixels, helping guarantee the uniformity of the mixed-color light of the display panel.

Exemplarily, among pixel units 110 in the same column, first pixel units 110A and second pixel units 110B are arranged alternately in the column direction Y.

With continued reference to FIGS. 2 to 9, among pixel units 110 in the same column, first pixel units 110A and second pixel units 110B are arranged alternately in the column direction Y so that a first pixel unit 110A and a second pixel unit 110B that are in the same row and adjacent to each other form a minimum repetition unit of pixel arrangement. Additionally, pixel units 110 in two adjacent rows include first pixel units 110A and second pixel units 110B. That is, pixel units 110 in two adjacent rows both include first color sub-pixels P1, second color sub-pixels P2, and third color sub-pixels P3, helping guarantee the uniformity of the mixed-color light of the display panel.

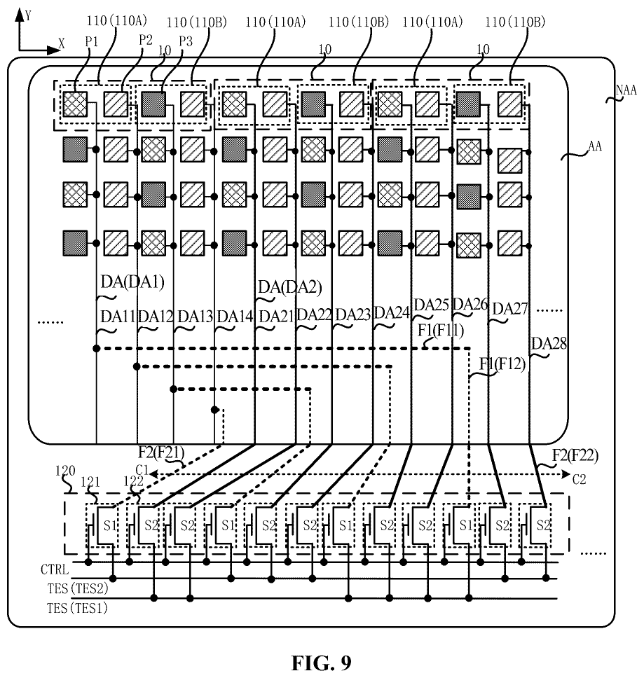

Exemplarily, FIG. 9 is a partial enlarged structure diagram of another display panel according to one or more embodiments of the present application. As shown in FIG. 9, among sub-pixels P in two adjacent columns, for sub-pixels P in one column, first color sub-pixels P1 and third color sub-pixels P3 are arranged alternately in the column direction Y; and sub-pixels P in the other column are second color sub-pixels P2.

Exemplarily, a first pixel unit 110A and a second pixel unit 110B each include a second color sub-pixel P2. When first pixel units 110A and second pixel units 110B are arranged alternately in the column direction Y among pixel units 110 in the same column, second color sub-pixels P2 in the first pixel units 110A and second pixel units 110B may be set in the same column, and first color sub-pixels P1 and third color sub-pixels P3 are in the same column and are arranged alternately in the column direction Y, helping guarantee the uniformity of the mixed-color light of the display panel.

Exemplarily, a first color sub-pixel P1 is a red sub-pixel, a second color sub-pixel P2 is a green sub-pixel, and a third color sub-pixel P3 is a blue sub-pixel. In this case, the pixel arrangement of the display panel is an RGBG arrangement. That is, red sub-pixels and blue sub-pixels are disposed in the same column, and green sub-pixels are disposed in the same column. Among sub-pixels in two adjacent columns, in sub-pixels in one column, red sub-pixels and blue sub-pixels are arranged alternately; and sub-pixels in the other column are green sub-pixels. Sub-pixels in the same row are circularly arranged in a sequence of a red sub-pixel, a green sub-pixel, a blue sub-pixel, and a green sub-pixel.

Exemplarily, each test circuit unit 120 includes four first switches 121 and eight second switches 122. Two data lines DA are disposed between two adjacent second connection lines F12. The four first switches 121 in each test circuit unit 120 are electrically connected to corresponding pixel units 110 in two adjacent columns. The eight second switches 122 in each test circuit unit 120 are electrically connected to corresponding pixel units 110 in four adjacent columns.

Exemplarily, when each of N, M, and K is 2, a pixel repetition unit 10 includes two pixel units 110. In this case, the pixel repetition unit 10 is electrically connected to four data lines DA. In this case, it may be set that a test circuit unit 120 includes four first switches 121 and eight second switches 122. Four first fan-out lines F1 and twelve second fan-out lines F2 are disposed correspondingly. A first fan-out line F1 includes a first connection line F11 and a second connection line F12. The four first switches 121 are electrically connected through second connection lines F12 to four first data lines DA1 electrically connected to one pixel repetition unit 10. Among the eight second switches 122, two adjacent second switches 122 are electrically connected to two data lines DA between two adjacent second connection lines F12. The eight second switches 122 are electrically connected to eight first data lines DA1 electrically connected to two adjacent pixel repetition units 10 in the same row. Therefore, the test circuit unit 120 can be electrically connected through the first fan-out lines F1 and the second fan-out lines F2 to three pixel repetition units 10 in the same row. Moreover, the corresponding connection relationship between the three pixel repetition units 10 in the same row and the test circuit unit 120 may serve as a minimum repetition unit of the corresponding connection relationship between the test circuit unit 120 and corresponding pixel units 110. When the display panel includes pixel units 110 in multiple rows and multiple columns, the corresponding connection between all test circuit units 120 and pixel units 110 in the display panel is implemented according to the minimum repetition unit of the corresponding connection relationship between the test circuit unit 120 and corresponding pixel units 110.

Exemplarily, among the four first switches 121 in each test circuit unit 120, two adjacent first switches 121 on one side of each test circuit unit 120 are electrically connected to corresponding pixel units 110 in a same column, and two other adjacent first switches 121 on the other side of the each test circuit unit 120 are electrically connected to corresponding pixel units 110 in a same column. In this case, two adjacent first switches 121 are electrically connected to two data lines DA of pixel units 110 in the same column, reducing the probability that lines between the first switches 121 and corresponding pixel units 110 electrically connected to the first switches 121 overlap in space, and thereby helping simplify wiring design.

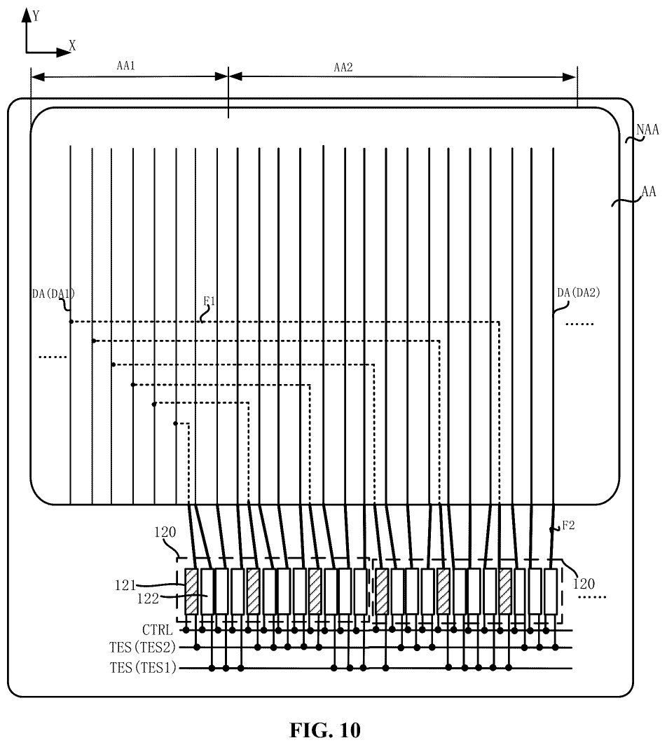

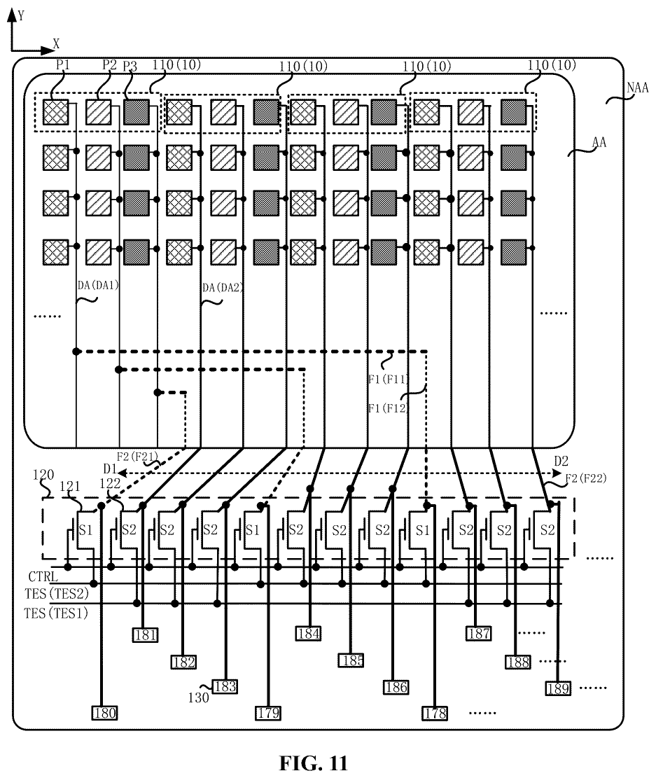

FIG. 10 is a partial structure diagram of another display panel according to one or more embodiments of the present application. FIG. 11 is a partial enlarged structure diagram of another display panel according to one or more embodiments of the present application. As shown in FIGS. 10 and 11, N is 3, M is 3, and K is 1. In this case, each pixel unit 110 is electrically connected to three data lines DA. Three data lines DA are disposed between two adjacent second connection lines F12. A pixel repetition unit 10 includes one pixel unit 110. A test circuit unit 120 may include three first switches 121 and nine second switches 122. The display panel includes three fan-out lines F1 and twelve second fan-out lines F2. The three first switches 121 are electrically connected to first fan-out lines F1 through second fan-out lines F2 respectively to supply a test signal to first data lines DA1 corresponding to the first fan-out lines F1. Moreover, the nine second switches 122 are electrically connected through second fan-out lines F2 to second data lines DA2 between second connection lines F12 to supply a test signal to second data lines DA2 corresponding to the second fan-out lines F2. When two test signal lines TES are included, second ends of switches electrically connected to corresponding pixel units 110 in the same column are electrically connected to the same test signal line TES, and second ends of switches electrically connected to corresponding pixel units 110 in two adjacent columns are electrically connected to different test signal lines TES. In this case, different test signals may be supplied to different test signal lines TES in the detection process of the display panel so that test signals acquired by pixel units 110 in two adjacent columns are different. When the display panel is normal, the display panel can present a detection image in which pixel units 110 are lit up in every other column. When the display panel is abnormal, the display panel fails to present a detection image in which pixel units 110 in are lit up in every other column. Therefore, whether the display panel is abnormal can be determined according to the detection image, thereby achieving the detection of defective display panels.

Exemplarily, adjacent second fan-out lines F2 may be arranged alternately in different layers. For example, the display panel includes a first conductive layer and a second conductive layer. One pixel repetition unit 10 electrically connected to the three first switches 121 are located on one side of the active area AA (for example, a first active area) relative to three pixel repetition units 10 electrically connected to the nine second switches 122. The arrangement sequence of the second fan-out lines F2 is opposite to the arrangement sequence of corresponding first data lines DA1 electrically connected to the second fan-out lines F2. The arrangement sequence of the second fan-out lines F2 is the same as the arrangement sequence of corresponding second data lines DA2 electrically connected to the second fan-out lines F2. For example, the twelve second fan-out lines F2 that correspond to the same test circuit unit and are arranged in the positive direction of the row direction X are located in the first conductive layer, the second conductive layer, the first conductive layer, the second conductive layer, the first conductive layer, the second conductive layer, the first conductive layer, the second conductive layer, the first conductive layer, the second conductive layer, the first conductive layer, and the second conductive layer respectively. Second fan-out lines F2 electrically connected to corresponding pixel units 110 in adjacent columns are at least partially disposed in the same layer and with no second fan-out line in the same layer in between so that a short circuit, when occurring, may be detected. For example, second fan-out lines F2 electrically connected to corresponding pixel units 110 in an odd column and second fan-out lines F2 electrically connected to corresponding pixel units 110 in an even column are at least partially disposed in the same layer and with no second fan-out line in the same layer in between so that a short circuit, when occurring, may be detected. When second ends of switches electrically connected to corresponding pixel units 110 in the same column are electrically connected to the same test signal line TES and second ends of switches electrically connected to corresponding pixel units 110 in two adjacent columns are electrically connected to different test signal line TES, different test signals may be supplied to different test signal lines TES in the detection process of the display panel so that test signals acquired by pixel units 110 in two adjacent columns are different. When the display panel is normal, the display panel can present a detection image in which pixel units are lit up in every other column. When a short circuit occurs in second fan-out lines F2 in the same layer, pixel units 110 in two adjacent columns can be lit up simultaneously, and the brightness of the pixel units 110 is between the maximum brightness and extinction, so that the display panel fails to present a detection image in which pixel units are lit up in every other column, thereby achieving the detection of the defective display panel based on the detection image.

In some embodiments, it may be also set that the display panel includes a first conductive layer, a second conductive layer, and a third conductive layer. Four pixel repetition units 10 electrically connected to the test circuit unit 120 may be adjacent to each other or partially adjacent to each other. One pixel repetition unit 10 electrically connected to the three first switches 121 are located on one side of the active area AA (for example, the first active area) relative to three pixel repetition units 10 electrically connected to the nine second switches 122. The arrangement sequence of the second fan-out lines F2 is opposite to the arrangement sequence of corresponding first data lines DA1 electrically connected to the second fan-out lines F2. The arrangement sequence of the second fan-out lines F2 is the same as the arrangement sequence of corresponding second data lines DA2 electrically connected to the second fan-out lines F2. In this case, the twelve second fan-out lines F2 arranged in the positive direction of the row direction X are located in the first conductive layer, the second conductive layer, the third conductive layer, the first conductive layer, the second conductive layer, the third conductive layer, the first conductive layer, the second conductive layer, the third conductive layer, the first conductive layer, the second conductive layer, and the third conductive layer respectively. Second fan-out lines F2 electrically connected to corresponding pixel units 110 in adjacent columns are at least partially disposed in the same layer and with no second fan-out line in the same layer in between so that a short circuit, when occurring, may be detected. For example, second fan-out lines F2 electrically connected to corresponding pixel units 110 in an odd column and second fan-out lines F2 electrically connected to corresponding pixel units 110 in an even column are at least partially disposed in the same layer and with no second fan-out line in the same layer in between so that a short circuit, when occurring, may be detected. When second ends of switches electrically connected to corresponding pixel units 110 in the same column are electrically connected to the same test signal line TES and second ends of switches electrically connected to corresponding pixel units 110 in two adjacent columns are electrically connected to different test signal line TES, different test signals may be supplied to different test signal lines TES in the detection process of the display panel so that test signals acquired by pixel units 110 in two adjacent columns are different. When the display panel is normal, the display panel can present a detection image in which pixel units are lit up in every other column. When a short circuit occurs in second fan-out lines F2 in the same layer, pixel units 110 in two adjacent columns can be lit up simultaneously, the brightness of the pixel units 110 is between the maximum brightness and extinction, so that the display panel fails to show a detection image in which pixel units are lit up at in every other column, thereby achieving the detection of the defective display panel based on the detection image.

M Additionally, pads 130 in four rows may be disposed in the non-active area NAA of the display panel. Pads 130 in each row include a plurality of pads 130 arranged in the row direction X. Pads 130 in one row are electrically connected to third fan-out lines F21 electrically connected to first switches 121. The arrangement sequence of the pads 130 in the row is opposite to the arrangement sequence of corresponding data lines DA electrically connected to the pads 130 in the row. Pads 130 in other three rows are electrically connected to fourth fan-out lines F22 electrically connected to second switches 122. The arrangement sequence of the pads 130 in the other three rows is the same as the arrangement sequence of corresponding data lines DA electrically connected to the pads 130 in the three other rows. With continued reference to FIG. 11, exemplarily, the sequence numbers of reverse-sequence pads are 180, 179, 178, . . . , and the like and are decreased sequentially. The sequence numbers of positive-sequence pads in one row may be 181, 184, 187, . . . , and the like and are increased sequentially. The sequence numbers of positive-sequence pads in another row may be 182, 185, 188, . . . , and the like and are increased sequentially. The sequence numbers of positive-sequence pads in another row may be 183, 186, 180, . . . , and the like and are increased sequentially. In FIG. 11, each row exemplarily illustrates three pads 130. The reverse-sequence pads may be set to be sequentially electrically connected to the third fan-out lines F21 electrically connected to the first switches 121 so that the sequence numbers of the reverse-sequence pads are opposite to the arrangement sequence of corresponding data lines DA electrically connected to the third fan-out lines F21 to match the port arrangement of the driver chip. In this case, the driver chip can supply drive signals to the data lines electrically connected to the third fan-out lines F21. Positive-sequence pads may be set to be sequentially electrically connected to the fourth fan-out lines F22 electrically connected to the second switches 122 so that the sequence change of the positive-sequence pads is the same as the arrangement sequence of corresponding data lines DA electrically connected to the fourth fan-out lines F22 to match the port arrangement of the driver chip. In this case, the driver chip can supply drive signals to the data lines electrically connected to the fourth fan-out lines F22 to implement the display of the display panel.

Exemplarily, any pixel unit 110 includes one first color sub-pixel P1, one second color sub-pixel P2, and one third color sub-pixel P3. Sub-pixels P in each row are circularly arranged in a sequence of a first color sub-pixel P1, a second color sub-pixel P2, and a third color sub-pixel P3. Sub-pixels P in each column are sub-pixels of the same color. Exemplarily, any pixel unit 110 includes one first color sub-pixel P1, one second color sub-pixel P2, and one third color sub-pixel P3 that are located in different columns.

Exemplarily, with continued reference to FIG. 10, a pixel unit 110 includes one first color sub-pixel P1, one second color sub-pixel P2, and one third color sub-pixel P3 that are arranged in the row direction X so that the pixel unit 110 has sub-pixels P in three columns which are connected to three corresponding data lines DA. Exemplarily, each pixel unit 110 includes one first color sub-pixel P1, one second color sub-pixel P2, and one third color sub-pixel P3, helping guarantee the uniformity of the mixed-color light of the display panel. Sub-pixels P in each row are circularly arranged in a sequence of a first color sub-pixel P1, a second color sub-pixel P2, and a third color sub-pixel P3 so that one pixel unit 110 is a minimum repetition unit of pixel arrangement in the row direction X.

Exemplarily, the first color sub-pixel P1 is a red sub-pixel, the second color sub-pixel P2 is a green sub-pixel, and the third color sub-pixel P3 is a blue sub-pixel. In this case, the pixel arrangement of the display panel is an RGB arrangement. Sub-pixels P in each row are circularly arranged in a sequence of a red sub-pixel, a blue sub-pixel, and a green sub-pixel. Moreover, red sub-pixels are in a same column, blue sub-pixels are in a same column, and green sub-pixels are also in a same column.

Exemplarily, each test circuit unit 120 includes three first switches 121 and nine second switches 122. Three data lines DA are disposed between two adjacent second connection lines F12. The three first switches 121 in each test circuit unit 120 are electrically connected to corresponding pixel units 110 in the same column. The eight second switches 122 in each test circuit unit 120 are electrically connected to corresponding pixel units 110 in three adjacent columns.

Exemplarily, when N is 3, M is 3, and K is 1, a pixel repetition unit 10 includes one pixel unit 110. In this case, the pixel repetition unit 10 is electrically connected to three data lines DA. In this case, it may be set that a test circuit unit 120 includes three first switches 121 and nine second switches 122. Three first fan-out lines F1 and twelve second fan-out lines F2 are disposed correspondingly. A first fan-out line F1 includes a first connection line F11 and a second connection line F12. The three first switches 121 are electrically connected through second connection lines F12 to three first data lines DA1 electrically connected to one pixel repetition unit 10. Among the nine second switches 122, three adjacent second switches 122 are electrically connected to three data lines DA between two adjacent second connection lines F12. Therefore, the test circuit unit 120 can be electrically connected through the first fan-out lines F1 and the second fan-out lines F2 to four pixel repetition units 10. Moreover, the corresponding connection relationship between the four pixel repetition units 10 and the test circuit unit 120 may serve as a minimum repetition unit of the corresponding connection relationship between the test circuit unit 120 and corresponding pixel units 110. When the display panel includes pixel units 110 in multiple rows and multiple columns, the corresponding connection between all test circuit units 120 and pixel units 110 in the display panel is achieved according to the minimum repetition unit of the corresponding connection relationship between the test circuit unit 120 and corresponding pixel units 110.

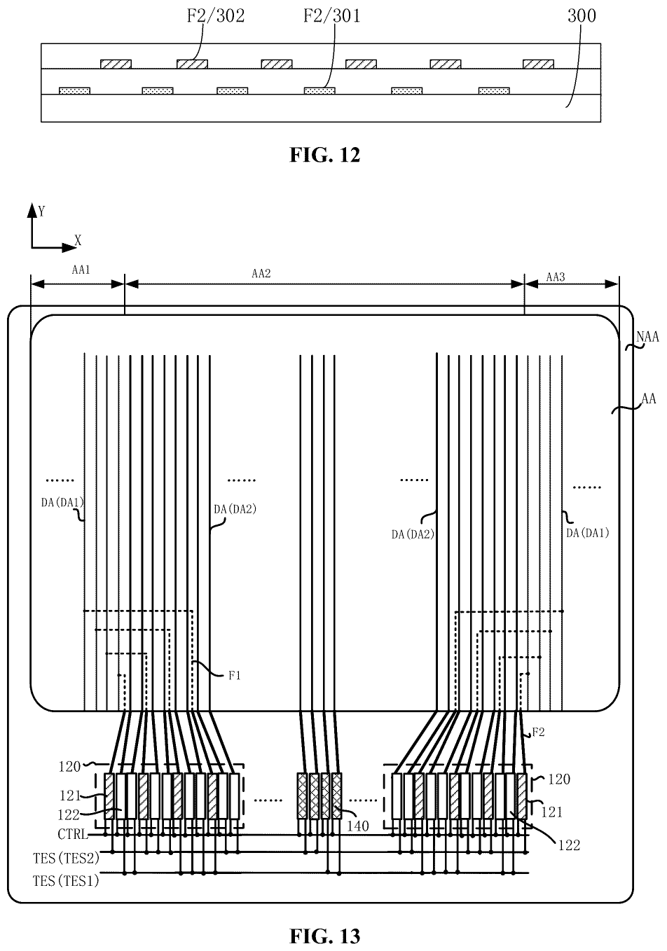

On the basis of the preceding embodiments, referring to FIG. 12, at least part of the second fan-out lines F2 are located in the same conductive layer. FIG. 12 may be a section view taken along a direction C1C2 of FIG. 9. FIG. 12 may be a section view taken along a direction D1D2 of FIG. 11.

Exemplarily, at least part of the second fan-out lines are located in the same conductive layer, are electrically connected to corresponding pixel units in different columns, and with no second fan-out line in the same layer in between. When second ends of switches electrically connected to corresponding pixel units in the same column are electrically connected to one test signal line and second ends of switches electrically connected to corresponding pixel units in adjacent columns are electrically connected to different test signal line, in the detection of the display panel, the display panel fails to present a detection image in which pixel units are lit up in every other column if a short circuit occurs between second fan-out lines in the same conductive layer. Therefore, it can be determined according to the detection image whether the display panel is abnormal, thereby achieving the detection of the defective display panel.

Exemplarily, referring to FIG. 11, the plurality of second fan-out lines F2 are arranged in the row direction. Two adjacent second fan-out lines F2 are located in different conductive layers (for example, the first conductive layer 301 and the second conductive layer 302 that are on a substrate 300 and may be metal layers). Among three adjacent second fan-out lines F2, two second fan-out lines F2 on two sides are located in the same conductive layer. An insulating layer may be disposed between adjacent conductive layers.

Exemplarily, the number of second fan-out lines is relatively great. The arrangement in which at least part of the adjacent second fan-out lines are located in different conductive layers guarantees the spacing between the second fan-out lines and simplifies the arrangement of the second fan-out lines. Moreover, two adjacent second fan-out lines are located in different conductive layers. Among three adjacent second fan-out lines F2, two second fan-out lines F2 on two sides are located in the same conductive layer. In this case, when arranged in the row direction, the second fan-out lines are disposed alternately in different conductive layers, further guaranteeing the spacing between the second fan-out lines. On the basis of the preceding embodiments, part or all of the second fan-out lines connected to corresponding pixel units in the same column may be disposed in different layers. At least part of the second fan-out lines connected to corresponding pixel units in adjacent columns may be disposed in the same layer.

On the basis of the preceding embodiments, FIG. 13 is a structure diagram of another display panel according to one or more embodiments of the present application. As shown in FIG. 13, the active area AA includes a first active area AA1, a second active area AA2, and a third active area AA3 that are arranged sequentially in the row direction X. The first data lines DA1 are located in the first active area AA1 and the third active area AA3. The second data lines DA2 are located in the second active area AA2.

Exemplarily, the first active area AA1 and the third active area AA3 are located on two sides of the active area AA in the row direction X. The second active area AA2 is located in the middle of the active area AA. The first active area AA1 and the third active area AA3 may be located on two opposite sides of the second active area AA2 in the row direction X. Exemplarily, each second connection line F12 is located in the second active area AA2. A longer second connection line F12 is closer to a data line in the middle of the second active area AA2.

Exemplarily, the number of first data lines DA1 corresponding to the first active area AA1 may be equal to the number of first data lines DA1 corresponding to the third active area AA3. Exemplarily, when the first active area AA1 corresponds to 360 first data lines DA1, the third active area AA3 also corresponds to 360 first data lines DA1. Moreover, the active area AA includes 2560 data lines DA. In this case, the second active area AA2 corresponds to 1840 second data lines DA2. The first first data line DA1 corresponding to the third active area AA3 is the 2201^{st} data line DA. Exemplarily, the data lines DA are numbered in a direction from the first active area AA1 to the second active area AA2. Data lines DA in the first active area AA1 are sequentially numbered 1 to 360. Data lines DA in the second active area AA2 are sequentially numbered 361 to 2200. Data lines DA in the third active area AA3 are sequentially numbered 2201 to 2560. Multiple test circuit units 120 connected to the first data lines DA1 in the first active area AA1 and multiple test circuit units 120 connected to the first data lines DA1 in the third active area AA3 may be arranged symmetrically, with the axis of symmetry parallel to the column direction. Multiple first fan-out lines F1 connected to the first data lines DA1 in the first active area AA1 and multiple first fan-out lines F1 connected to the first data lines DA1 in the third active area AA3 may be arranged symmetrically, with the axis of symmetry parallel to the column direction. Multiple second fan-out lines F2 connected to the first data lines DA1 in the first active area AA1 and multiple second fan-out lines F2 connected to the first data lines DA1 in the third active area AA3 may be arranged symmetrically, with the axis of symmetry parallel to the column direction. Exemplarily, the display panel may also include one or more third switches 140. A first end of a third switch 140 may be electrically connected through a corresponding second fan-out line F2 to a corresponding second data line DA2. A second end of the third switch 140 may be electrically connected to a corresponding test signal line. Test circuit units 120 may be located on two opposite sides of the third switch 140 in the direction X. A control end of the third switch 140 may be electrically connected to the control signal line CTRL. Pixel units in the same column electrically connected to the third switch 140 are electrically connected to the same test signal line. Pixel units in two adjacent columns electrically connected to the third switches 140 are electrically connected to different test signal lines through the third switch 140. For example, pixel units in an odd column electrically connected to third switches 140 are electrically connected to the first test signal line TES1 through the third switches 140, and pixel units in an even column electrically connected to third switches 140 are electrically connected to the second test signal line TES2 through the third switches 140. In the detection of the display panel, one of the first test signal line TES1 and the second test signal line TES2 may be used for inputting the lighting voltage, and the other one may be used for inputting the extinction voltage. When the display panel is normal, the display panel can show a detection image in which pixel units 110 in two adjacent columns are lit up alternately. When the display panel is abnormal, the display panel fails to present a detection image in which pixel units 110 in one column of two adjacent columns are lit up, and pixel units 110 in other column of two adjacent columns are not lit up. Therefore, it can be determined according to the detection image whether the display panel is abnormal, thereby achieving the detection of the defective display panel. Exemplarily, a third switch 140 of the one or more third switches 140 includes a third transistor. A first electrode of the third transistor serves as the first end of the third switch 140. A second electrode of the third transistor serves as the second end of the third switch 140. A control electrode of the third transistor serves as the control end of the third transistor 140.

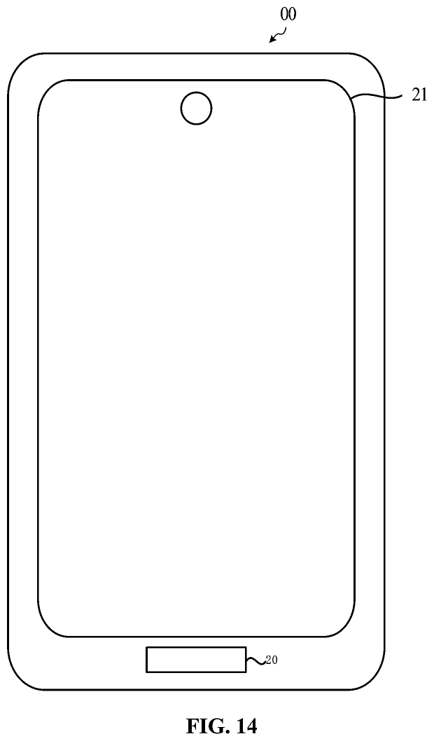

Embodiments of the present application further provide a display device. FIG. 14 is a structure diagram of a display device according to one or more embodiments of the present application. As shown in FIG. 14, the display device 00 includes a driver chip 20 and the display panel 21 provided in any embodiment of the present application. The driver chip 20 is electrically connected to second fan-out lines.

Exemplarily, the driver chip 20 is electrically connected to the second fan-out lines and can supply drive signals to the display panel through the second fan-out lines. Exemplarily, the display panel may further include one or more pads located in a bonding area. The driver chip 20 may be bonded to the pads and thus is electrically connected to the second fan-out lines. The display device 00 includes the display panel provided in any embodiment of the present application and thus has the same beneficial effects as the display panel provided in any embodiment of the present application. The details are not repeated here. The display device 00 may be any product or component with a display function, such as a mobile phone, a tablet computer, a television, a display, a laptop, or a digital photo frame.

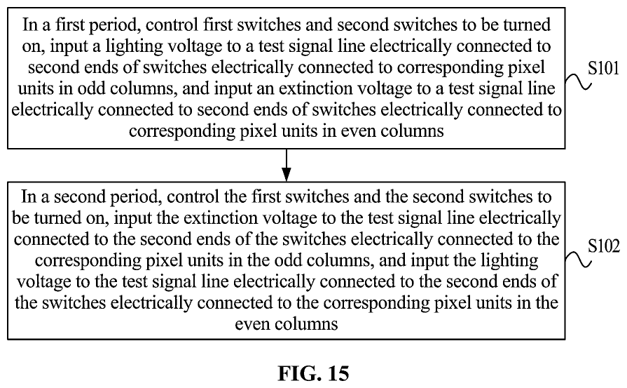

Embodiments of the present application further provide a test method of a display panel. The method is applied to the display panel provided in any embodiment of the present application. FIG. 15 is a flowchart of a test method of a display panel according to one or more embodiments of the present application. As shown in FIG. 15, the test method includes step S101 and/or step S102.

In S101, in a first period, the first switches and the second switches are controlled to be turned on, a lighting voltage is input to a test signal line electrically connected to second ends of switches electrically connected to corresponding pixel units in odd columns, and an extinction voltage is input to a test signal line electrically connected to second ends of switches electrically connected to corresponding pixel units in even columns.

When the display panel is normal and when the first switches and the second switches are turned on, the lighting voltage is input through the first switches and/or the second switches to the pixel units in the odd columns to enable the pixel units in the odd columns to be lit up. When the display panel is normal, the extinction voltage is input through the first switches and/or the second switches to the pixel units in the even columns to enable the pixel units in the even columns to be extinct. When the display panel is normal, the pixel units in the odd columns are lit up, and the pixel units in the even columns are extinct. When the display panel is abnormal, pixel units in at least one odd column are extinct, and/or pixel units in at least one even column are lit up, and/or the brightness between pixel units in at least two columns is between the brightness and extinction of a pixel unit lit up normally. Therefore, it can be determined according to the brightness condition of the pixel units in the odd columns and the brightness condition of the pixel units in the even columns, achieving the detection of the defective display panel. Exemplarily, the display panel may further include one or more third switches 140. In the first period, the first switches, the second switches, and the third switches are controlled to be turned on.

In S102, in a second period, the first switches and the second switches are controlled to be turned on, the extinction voltage is input to the test signal line electrically connected to the second ends of the switches electrically connected to the corresponding pixel units in the odd columns, and the lighting voltage is input to the test signal line electrically connected to the second ends of the switches electrically connected to the corresponding pixel units in the even columns.

When the display panel is normal and when the first switches and the second switches are turned on, the extinction voltage is input through the first switches and/or the second switches to the pixel units in the odd columns to enable the pixel units in the odd columns to be extinct. When the display panel is normal, the lighting voltage is input through the first switches and/or the second switches to the pixel units in the even columns to enable the pixel units in the even columns to be lit up. When the display panel is normal, the pixel units in the odd columns are extinct, and the pixel units in the even columns are lit up. When the display panel is abnormal, pixel units in at least one odd column are lit up, and/or pixel units in at least one even column are extinct, and/or the brightness between pixel units in at least two columns is between the brightness and extinction of a pixel unit lit up normally. Therefore, it can be determined according to the brightness condition of the pixel units in the odd columns and the brightness condition of the pixel units in the even columns, achieving the detection of the defective display panel. Exemplarily, the display panel may further include the one or more third switches 140. In the second period, the first switches, the second switches, and the third switches are controlled to be turned on.

The sequence of the first period and the second period is not limited Exemplarily, the first period is before the second period; alternatively, the first period is after the second period.

For the solution in embodiments of the present application, in the first period, the first switches and the second switches are controlled to be turned on, the lighting voltage is input to the test signal line electrically connected to the second ends of the switches electrically connected to the corresponding pixel units in the odd columns, and the extinction voltage is input to the test signal line electrically connected to the second ends of switches electrically connected to the corresponding pixel units in the even columns. In some embodiments, in the second period, the first switches and the second switches are controlled to be turned on, the extinction voltage is input to the test signal line electrically connected to the second ends of the switches electrically connected to the corresponding pixel units in the odd columns, and the lighting voltage is input to the test signal line electrically connected to the second ends of the switches electrically connected to the corresponding pixel units in the even columns. With this arrangement, test signals acquired by pixel units in two adjacent columns are different. When the display panel is normal, the display panel can present a detection image in which pixel units are lit up in every other column. When the display panel is abnormal, the display panel fails to present a detection image in which pixel units are lit up in every other column. Therefore, whether the display panel is abnormal can be determined according to the detection image, thereby achieving the detection of the defective display panel.

What is claimed is:

1. A display panel, comprising an active area and a non-active area and further comprising:
a plurality of pixel units arranged in an array and located in the active area;
a plurality of data lines located in the active area, the plurality of data lines are electrically connected to pixel units in corresponding columns, the plurality of data lines extend in a column direction and are arranged in a row direction, and the plurality of data lines comprise at least two first data lines and at least two second data lines;
a plurality of first fan-out lines located in the active area, the plurality of first fan-out lines are electrically connected to corresponding first data lines;
a plurality of second fan-out lines located in the non-active area;
a plurality of test circuit units located in the non-active area, each test circuit unit comprises a plurality of switches, the plurality of switches comprise a plurality of first switches and a plurality of second switches, first ends of the plurality of first switches are electrically connected to the plurality of first fan-out lines through corresponding second fan-out lines, and first ends of the plurality of second switches are electrically connected to corresponding second data lines through corresponding second fan-out lines; and
at least two test signal lines located in the non-active area;
wherein second ends of switches electrically connected to corresponding pixel units in a same column are electrically connected to a same one test signal line; and second ends of switches electrically connected to corresponding pixel units in two adjacent columns are electrically connected to different test signal lines.

2. The display panel according to claim 1, wherein the at least two test signal lines comprise a first test signal line and a second test signal line; and
second ends of switches electrically connected to corresponding pixel units in an odd column are electrically connected to the first test signal line, and second ends of switches electrically connected to corresponding pixel units in an even column are electrically connected to the second test signal line.

3. The display panel according to claim 1, further comprising a control signal line, wherein control ends of the plurality of first switches and control ends of the plurality of second switches are electrically connected to the control signal line.

4. The display panel according to claim 3, wherein a first switch of the plurality of first switches comprises a first transistor, a first electrode of the first transistor serves as a first end of the first switch, a second electrode of the first transistor serves as a second end of the first switch, and a control end of the first transistor serves as the control end of the first switch; and
a second switch of the plurality of second switches comprises a second transistor, a first electrode of the second transistor serves as a first end of the second switch, a second electrode of the second transistor serves as a second end of the second switch, and a control end of the second transistor serves as the control end of the second switch.

5. The display panel according to claim 1, wherein
an arrangement sequence of the plurality of second fan-out lines in the row direction is different from an arrangement sequence of corresponding data lines electrically connected to the plurality of second fan-out lines;
first ends of first fan-out lines, electrically connected to second fan-out lines are closer to a second data line located in a middle of the active area compared with second ends of the first fan-out lines electrically connected to the first data lines; and
the plurality of second fan-out lines are arranged in the row direction, and an outermost second fan-out line is electrically connected to a first end of a first switch.

6. The display panel according to claim 1, wherein each of the plurality of first fan-out lines comprises a first connection line and a second connection line that are electrically connected to each other, the second connection line is electrically connected to a corresponding first data line through the first connection line;
a plurality of second connection lines of the plurality of first fan-out lines extend in the column direction and are arranged in the row direction, and N data lines are disposed between two adjacent second connection lines, wherein N is an integer greater than or equal to 2;
any pixel unit among the plurality of pixel units comprises M sub-pixels or is electrically connected to M data lines, wherein M is an integer greater than or equal to 2; and any one of the plurality of test circuit units comprises K*M first switches and N*K*M second switches, wherein K is an integer greater than or equal to 1; and
the plurality of pixel units are divided into at least two pixel repetition units, and any one pixel repetition unit comprises K pixel units.

7. The display panel according to claim 6, wherein the plurality of second fan-out lines comprise at least two third fan-out lines and at least two fourth fan-out lines, the third fan-out lines are electrically connected to first ends of first switches, and the fourth fan-out lines are electrically connected to first ends of second switches; and
the plurality of second fan-out lines are arranged in the row direction; an arrangement sequence of the at least two third fan-out lines is opposite to an arrangement sequence of corresponding first data lines electrically connected to the at least two third fan-out lines; and an arrangement sequence of the at least two fourth fan-out lines is same as an arrangement sequence of corresponding second data lines electrically connected to the at least two fourth fan-out lines.

8. The display panel according to claim 7, wherein
N fourth fan-out lines are disposed between two adjacent third fan-out lines and are electrically connected to corresponding pixel units in a same column; and among 2N fourth fan-out lines among three adjacent t third fan-out lines, N fourth fan-out lines and another N fourth fan-out lines are electrically connected to corresponding pixel units in different columns; and
in the each test circuit unit, the plurality of first switches and the plurality of second switches are arranged in the row direction, and N second switches are disposed between two adjacent first switches.

9. The display panel according to claim 7, in the each test circuit unit, second ends of N second switches between two adjacent first switches are electrically connected to a same one test signal lines; and in 2N second switches among three adjacent first switches, a test signal line electrically connected to second ends of N second switches is different from a test signal line electrically connected to second ends of another N switches.

10. The display panel according to claim 6, wherein the plurality of first switches in the each test circuit unit are electrically connected to corresponding pixel units in a column or corresponding pixel units in at least two adjacent columns, and the plurality of second switches in the each test circuit unit are electrically connected to corresponding pixel units in multiple adjacent columns, wherein M is equal to N.

11. The display panel according to claim 7, further comprising pads in N+1 rows located in the non-active area; pads in each row comprise a plurality of pads arranged in the row direction; pads in one row are electrically connected to third fan-out lines electrically connected to first switches, and an arrangement sequence of the pads in the one row is opposite to an arrangement sequence of corresponding data lines electrically connected to the pads in the one row; and pads in another N rows are electrically connected to fourth fan-out lines electrically connected to second switches, and an arrangement sequence of the pads in the another N rows is same as an arrangement sequence of corresponding data lines electrically connected to the pads in the another N rows.

12. The display panel according to claim 6, wherein N is 2, M is 2, and K is 2;
the plurality of pixel units comprise at least two first pixel units and at least two second pixel units; each of the at least two first pixel units comprises one first color sub-pixel and one second color sub-pixel; each of the at least two second pixel units comprises one third color sub-pixel and one second color sub-pixel; and among pixel units in a same row, first pixel units and second pixel units are arranged alternately in the row direction;
among pixel units in a same column, first pixel units and second pixel units are arranged alternately in the column direction;
among sub-pixels in two adjacent columns, for sub-pixels in one column, first color sub-pixels and third color sub-pixels are arranged alternately in the column direction; and sub-pixels in another column are second color sub-pixels; and
the first color sub-pixel is a red sub-pixel, the second color sub-pixel is a green sub-pixel, and the third color sub-pixel is a blue sub-pixel.

13. The display panel according to claim 12, wherein the each test circuit unit comprises four first switches and eight second switches, two data lines are disposed between the two adjacent second connection lines, the four first switches in the each test circuit unit are electrically connected to corresponding pixel units in two adjacent columns, and the eight second switches in the each test circuit unit are electrically connected to corresponding pixel units in four adjacent columns; and
among the four first switches in the each test circuit unit, two adjacent first switches on one side of the each test circuit unit are electrically connected to corresponding pixel units in a same column, and another two adjacent first switches on another side of the each test circuit unit are electrically connected to corresponding pixel units in a same column.

14. The display panel according to claim 6, wherein N is 3, M is 3, and K is 1;
the any pixel unit among the plurality of pixel units comprises one first color sub-pixel, one second color sub-pixel, and one third color sub-pixel; sub-pixels in each row are circularly arranged in a sequence of a first color sub-pixel, a second color sub-pixel, and a third color sub-pixel; and sub-pixels in each column are sub-pixels of a same color; and
the first color sub-pixel is a red sub-pixel, the second color sub-pixel is a green sub-pixel, and the third color sub-pixel is a blue sub-pixel.

15. The display panel according to claim 14, wherein the each test circuit unit comprises three first switches and nine second switches, and three data lines are disposed between two adjacent second connection lines; and
the three first switches in the each test circuit unit are electrically connected to corresponding pixel units in a same column, and the nine second switches in the each test circuit unit are electrically connected to corresponding pixel units in three adjacent columns.

16. The display panel according to claim 6, wherein a plurality of first connection lines of the plurality of first fan-out lines extend in the row direction; and in the plurality of first connection lines arranged in the column direction, a corresponding first data line, electrically connected to a longer first connection line is closer to a bezel of the display panel, and a corresponding second connection line electrically connected to the longer first connection line is longer.

17. The display panel according to claim 1, wherein at least part of the plurality of second fan-out lines are located in a same conductive layer; and
the plurality of second fan-out lines are arranged in the row direction; two adjacent second fan-out lines are located in different conductive layers; and among three adjacent second fan-out lines, two second fan-out lines on two sides are located in a same conductive layer.

18. The display panel according to claim 1, wherein the active area comprises a first active area, a second active area, and a third active area that are arranged sequentially in the row direction; the at least two first data lines are located in the first active area and the third active area; and the at least two second data lines are located in the second active area.

19. A display device, comprising a driver chip and the display panel according to claim 1, wherein the driver chip is electrically connected to the plurality of second fan-out lines.

20. A test method applied to the display panel according to claim 1, comprising:
in a first period, controlling the first switches and the second switches to be turned on, inputting a lighting voltage to a test signal line electrically connected to second ends of switches electrically connected to corresponding pixel units in odd columns, and inputting an extinction voltage to a test signal line electrically connected to second ends of switches electrically connected to corresponding pixel units in even columns; and,
in a second period, controlling the first switches and the second switches to be turned on, inputting the extinction voltage to the test signal line electrically connected to the second ends of the switches electrically connected to the corresponding pixel units in the odd columns, and inputting the lighting voltage to the test signal line electrically connected to the second ends of the switches electrically connected to the corresponding pixel units in the even columns.
